(19) United States
(12) Patent Application Publication
(10) Pub. No.: US 2020/0404818 A1
(43) Pub. Date: Dec. 24, 2020

(54) COMPONENT REPLENISHMENT MANAGEMENT SYSTEM AND COMPONENT MOUNTING SYSTEM

(71) Applicant: YAMAHA HATSUDOKI KABUSHIKI KAISHA, Iwata-shi, Shizuoka-ken (JP)

(72) Inventor: Yoichi MATSUSHITA, Shizuoka (JP)

(73) Assignee: YAMAHA HATSUDOKI KABUSHIKI KAISHA, Iwata-shi, Shizuoka-ken (JP)

(21) Appl. No.: 16/969,174

(22) PCT Filed: Feb. 28, 2018
(86) PCT No.: PCT/JP2018/007456

§ 371 Date: Aug. 11, 2020

(51) Int. Cl. H05K 13/08; H05K 13/02; H05K 13/04

(52) U.S. Cl. CPC H05K 13/086; H05K 13/0417; H05K 13/02

(57) ABSTRACT

This component replenishment management system is provided with an acquisition unit, a setting unit, a component supply monitoring unit, and a replenishment target specifying unit. The acquisition unit acquires a management start time for replenishing reels corresponding to each of a plurality of component supply devices. The setting unit sets a specified period until a specified time after a predetermined specified length of time has elapsed from the management start time. The component supply monitoring unit specifies, for each component supply device, a replenishment possibility time at which said component supply device can be replenished with a new reel. The replenishment target specifying unit specifies a component supply device in which the replenishment possibility time is an earlier time than the specified time as a component replenishment target device to be replenished with a new reel within the specified period.

### CROSS-REFERENCE TO RELATED APPLICATION

This application is a National Stage of International Patent Application No. PCT/JP2018/007456, filed Feb. 28, 2018, the entire content of which is incorporated herein by reference.

### BACKGROUND

### Technical Field

The present disclosure relates to a component replenishment management system that manages the replenishment of a component storage member storing a component with respect to a component supply device which is attached to a mounter that mounts components on a substrate and which is capable of loading the component storage member, and also relates to a component mounting system provided with the same.

### Background Art

Mounters that mount electronic components (hereinafter simply referred to as “components”) on a substrate such as a printed wiring board to produce a mounted substrate are provided with component supply devices capable of loading a component storage member storing the components. When producing a mounted substrate with a mounter, setup work such as loading a component storage member necessary for production into a component supply device is performed by a worker based on the production plan, and thereafter production is started. During the production of the mounted substrate, to avoid an interruption in the supply of components from the component supply device that causes an interruption in the production of the mounted substrate, replenishment work for replenishing the component supply device with the component storage member is performed by a worker according to the consumption of components associated with the production of the mounted substrate.

Technology for improving the efficiency of the replenishment work by the worker is disclosed in Japanese Unexamined Patent Application Publication No. 2012-28660, for example. According to the technology disclosed in Japanese Unexamined Patent Application Publication No. 2012-28660, on a component mounting line where a plurality of mounters are disposed, a process of predicting a time period during which to give advance notice of a component shortage in a plurality of component supply devices (feeders) attached to each mounter is executed, and a process of allocating a worker to perform the replenishment work in the advance notice time period of the component shortage is executed.

### SUMMARY

However, according to the technology disclosed in Japanese Unexamined Patent Application Publication No. 2012-28660, the replenishment timing of the component storage member for each component supply device is set individually. For this reason, if one attempts to perform the replenishment work by following the replenishment timings individually set for each component supply device, the worker frequently needs to go to the mounters where the component supply devices are attached, and must hurry from mounter to mounter. As a result, the replenishment work imposes a large burden on the worker.

The present disclosure has been devised in light of such circumstances, and provides a component replenishment management system capable of reducing the burden imposed on the worker by the replenishment work of replenishing a component supply device with a component storage member, as well as a component mounting system provided with the same.

A component replenishment management system according to an aspect of the present disclosure is a system that manages a replenishment of component storage members storing components with respect to each of a plurality of component supply devices attached to a mounter that mounts the components on a substrate to produce a mounted substrate, a plurality of the component storage members being loadable into each of the plurality of component supply devices. This component replenishment management system includes an acquisition unit that acquires a management start time expressing a start time of the management of the replenishment of the component storage members with respect to each of the plurality of component supply devices, a setting unit that sets a specified period until a specified time after a predetermined specified length of time has elapsed from the management start time, a component supply monitoring unit that monitors a supply status of the components in each of the plurality of component supply devices, and specifies, for each of the plurality of component supply devices, a replenishment possibility time at which a preceding component storage member used to supply the components from among the plurality of component storage members runs out of components and replenishment with a new component storage member becomes possible, and a replenishment target specifying unit that specifies a component supply device whose replenishment possibility time is an earlier time than the specified time as a component replenishment target device targeted for replenishment with a new component storage member within the specified period.

A component mounting system according to another aspect of the present disclosure includes a mounter to which a plurality of component supply devices loadable with a plurality of component storage members storing components is attached, the mounter mounting the components on a substrate to produce a mounted substrate, and the component replenishment management system that manages a replenishment of the component storage members with respect to each of the plurality of component supply devices.

Objects, features, and advantages of the present disclosure will be become more apparent by the following detailed description and the accompanying drawings.

### BRIEF DESCRIPTION OF THE DRAWINGS

FIG. 1 is a diagram schematically illustrating a configuration of a component mounting system according to an embodiment of the present disclosure;

FIG. 2 is a plan view illustrating a configuration of a mounter;

FIG. 3 is a diagram schematically illustrating a configuration of a component supply unit in the mounter;

FIG. 4 is an explanatory diagram of a component supply operation in a component supply device of the component supply unit;

FIG. 5 is an explanatory diagram of a component supply operation in a component supply device of the component supply unit;

FIG. 6 is an explanatory diagram of a component supply operation in a component supply device of the component supply unit;

FIG. 7 is a perspective view illustrating a component storage tape loaded into the component supply device in the component supply unit;

FIG. 8 is a block diagram illustrating a configuration of a first component replenishment management system according to a first embodiment;

FIG. 9 is a table for explaining production plan information input into the first component replenishment management system;

FIG. 10 is a table for explaining setup information input into the first component replenishment management system;

FIG. 11 is a chart for explaining control operations by the first component replenishment management system;

FIG. 12 is a diagram for explaining replenishment specification result information generated by a replenishment target specifying unit of the first component replenishment management system;

FIG. 13 is a chart for explaining control operations in a case where a component replenishment target device does not exist within a management period;

FIG. 14 is a chart for explaining control operations in a case where a component supply device whose remaining count warning time is earlier than the management period exists;

FIG. 15 is a chart for explaining a first modification of replenishment timing specifying operations by a replenishment timing specifying unit of the first component replenishment management system;

FIG. 16 is a chart for explaining the first modification of replenishment timing specifying operations by a replenishment timing specifying unit of the first component replenishment management system;

FIG. 17 is a chart for explaining a second modification of replenishment timing specifying operations by a replenishment timing specifying unit of the first component replenishment management system;

FIG. 18 is a block diagram illustrating a configuration of a second component replenishment management system according to a second embodiment;

FIG. 19 is a chart for explaining control operations by the second component replenishment management system;

FIG. 20 is a chart for explaining a first modification of control operations by the second component replenishment management system;

FIG. 21 is a chart for explaining a second modification of control operations by the second component replenishment management system;

FIG. 22 is a diagram for explaining replenishment specification result information generated by a replenishment target specifying unit of the second component replenishment management system;

FIG. 23 is a chart for explaining operations by an adjustment unit of the second component replenishment management system;

FIG. 24 is a table for explaining adjustment result information generated by the adjustment unit;

FIG. 25 is a diagram illustrating a tray feeder as the component supply device of the first modification;

FIG. 26 is a diagram illustrating a tray feeder as the component supply device of the second modification;

FIG. 27 is a diagram illustrating a stick feeder as the component supply device of a third modification; and

FIG. 28 is a diagram illustrating a stick feeder as the component supply device of a fourth modification.

### DETAILED DESCRIPTION

Hereinafter, a component replenishment management system and a component mounting system according to embodiments of the present disclosure will be described based on the drawings.

[Overall Configuration of Component Mounting System]

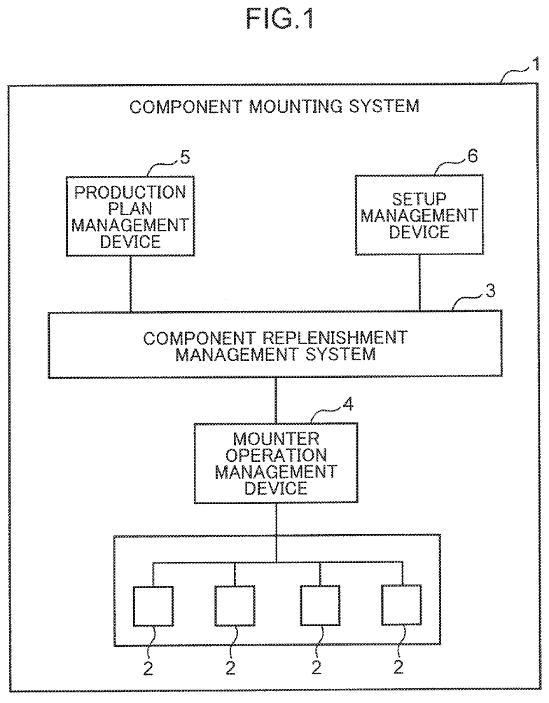

FIG. 1 is a diagram schematically illustrating a configuration of a component mounting system 1 according to an embodiment of the present disclosure. The component mounting system 1 is provided with mounters 2, a component replenishment management system 3, a mounter operation management device 4, a production plan management device 5, and a setup management device 6. In the component mounting system 1, the mounter operation management device 4, the production plan management device 5, and the setup management device 6 are management devices that are communicably connected to the component replenishment management system 3, and manage the production of a mounted substrate by the mounters 2. In the component mounting system 1, a plurality of mounters 2 are disposed in parallel. Note that in the example illustrated in FIG. 1, four mounters 2 are disposed in parallel.

<Configuration of Mounter>

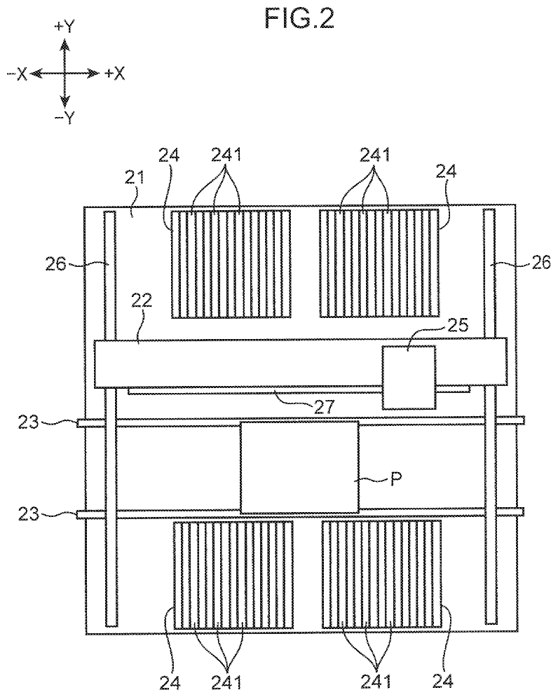

First, the configuration of each mounter 2 will be described with reference to FIG. 2. FIG. 2 is a plan view illustrating a configuration of one of the mounters 2. Note that in the following, directional relationships will be described using XY orthogonal coordinate axes. The side of one direction of the X-axis direction is referred to as the “+X side”, while the other side in the opposite direction of the X-axis direction is referred to as the “−X side”. Likewise, the side of one direction of the Y-axis direction is referred to as the “+Y side”, while the other side in the opposite direction of the Y-axis direction is referred to as the “−Y side”.

The mounters 2 are devices that mount components on a substrate P to produce a mounted substrate. Each mounter 2 is provided with a body frame 21, a moving frame 22, a conveyor 23, component supply units 24, a head unit 25, a first driving mechanism 26, and a second driving mechanism 27.

The body frame 21 is a structure on which each unit forming one of the mounters 2 is disposed, and is formed to have a substantially rectangular shape in plan view as seen from a direction orthogonal to both the X-axis direction and the Y-axis direction. The conveyor 23 is disposed on the body frame 21, extending in the X-axis direction. The conveyor 23 conveys the substrate P in the X-axis direction. The substrate P is conveyed on the conveyor 23 to be positioned at a predetermined work position (a mounting position where components are mounted onto the substrate P).

A total of four component supply units 24 are disposed two at a time in the X-axis direction in each of a region on the +Y side and the −Y side in the Y-axis direction on the body frame 21. Each component supply unit 24 supplies components to be mounted onto the substrate P, and is provided with a plurality of component supply devices 241. The component supply devices 241 are devices capable of loading a component storage member storing the components. In the present embodiment, the component supply devices 241 are tape feeders in which component storage tape, in which components are stored at predetermined intervals, is wound around a reel as the component storage member, and are configured such that the component storage tape is fed from the reel.

Generally, tape feeders are roughly categorized into splicing feeders and auto-loading feeders (AFs). A splicing feeder is configured such that a single reel is loaded, and in order to switch from a preceding component storage tape to a succeeding component storage tape before the preceding component storage tape is fed completely from the reel and a component shortage occurs, splicing tape or the like is applied to join the trailing end of the preceding component storage tape to the leading end of the succeeding component storage tape. In other words, in a splicing feeder, the splicing work of applying the splicing tape or the like is performed before the component storage tape is fed completely from a single reel and a component shortage occurs, and consequently the replenishment timing for the reel around which the succeeding component storage tape is wound is restricted to the point in time when the feeding of the preceding component storage tape is completed.

On the other hand, an AF is configured such that a plurality of reels are loadable, and when the feeding of a component storage tape from a preceding reel around which a component storage tape used to supply preceding components (hereinafter referred to as the “preceding component storage tape”) is wound is completed from among the plurality of reels, a component storage tape is automatically fed from a succeeding reel around which a succeeding component storage tape is wound, without performing splicing work. In other words, in an AF, the replenishment timing of a new reel is not restricted to the point in time when the feeding of the component storage tape from the preceding reel around which the preceding component storage tape is wound is completed, which provides a higher degree of freedom than a splicing feeder.

In the present embodiment, both splicing feeders and AFs may coexist as the tap feeders provided in the component supply units 24, but a plurality of AFs capable of loading multiple reels as the component storage member are disposed as the component supply devices 241. Component supply devices 241 configured as AFs are hereinafter referred to as “AFs 241”. Details regarding the AFs 241 will be described later.

The moving frame 22 extends in the X-axis direction and is supported by the body frame 21 to be movable in a predetermined movement direction (Y-axis direction). The head unit 25 is mounted on the moving frame 22. The head unit 25 is mounted on the moving frame 22 to be movable in the X-axis direction. In other words, the head unit 25 is capable of moving in the Y-axis direction in association with the movement of the moving frame 22, and is furthermore capable of moving in the X-axis direction along the moving frame 22. The head unit 25 is capable of moving back and forth between the component supply units 24 and the predetermined work position of the substrate P conveyed by the conveyor 23, picking up components from the component supply units 24 and also mounting the picked-up components onto the substrate P.

The first driving mechanism 26 is disposed at the ends on the +X side and the −X side of the body frame 21. The first driving mechanism 26 is a mechanism that causes the moving frame 22 to move in the Y-axis direction. The first driving mechanism 26 includes a driving motor, a ball screw shaft extending in the Y-axis direction and coupled to the driving motor, and a ball nut disposed on the moving frame 22 to engage with the ball screw shaft, for example. The first driving mechanism 26 with such a configuration causes the moving frame 22 to move in the Y-axis direction by causing the ball nut to advance or retreat along the ball screw shaft in association with the rotation of the ball screw shaft driven by the driving motor.

The second driving mechanism 27 is disposed on the moving frame 22. The second driving mechanism 27 is a mechanism that causes the head unit 25 to move in the X-axis direction along the moving frame 22. Like the first driving mechanism 26, the second driving mechanism 27 includes a driving motor, a ball screw shaft extending in the X-axis direction and coupled to the driving motor, and a ball nut disposed on the head unit 25 to engage with the ball screw shaft. The second driving mechanism 27 with such a configuration causes the head unit 25 to move in the X-axis direction by causing the ball nut to advance or retreat along the ball screw shaft in association with the rotation of the ball screw shaft driven by the driving motor.

<Configuration of Component Supply Unit Provided with AF>

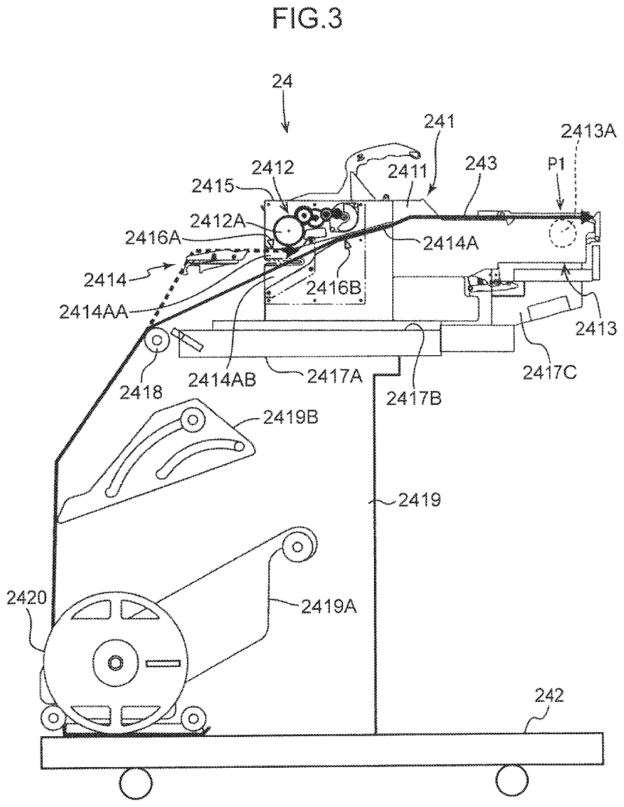

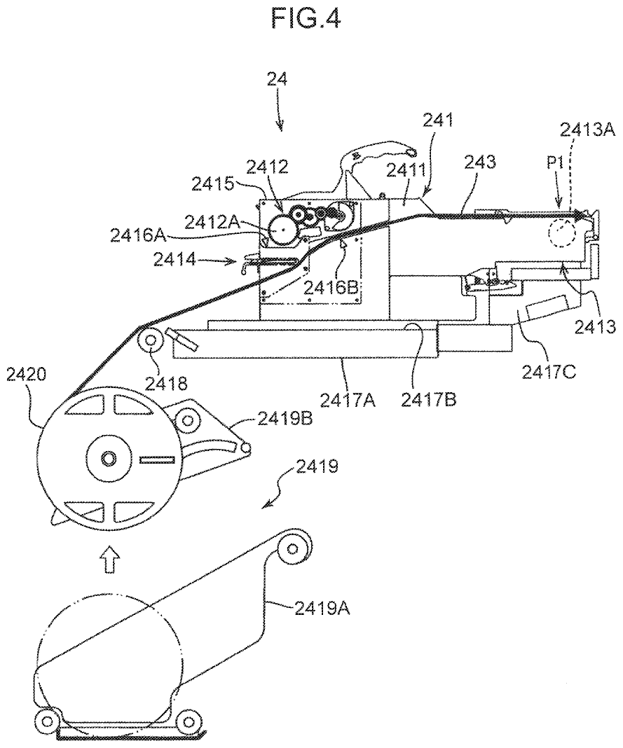

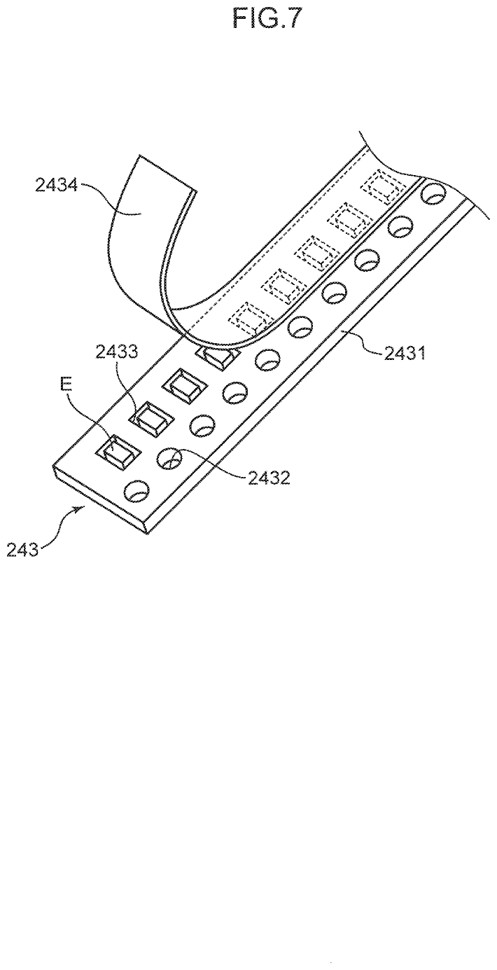

Next, FIGS. 3 to 7 will be referenced to describe the configuration of each component supply unit 24 provided with the AFs 241. FIG. 3 is a diagram schematically illustrating a configuration of one of the component supply units 24 in one of the mounters 2. FIGS. 4 to 6 are diagrams explaining component supply operations in the AFs 241 of one of the component supply units 24. FIG. 7 is a perspective view illustrating a component storage tape 243 loaded into the AFs 241 in one of the component supply units 24.

In each component supply unit 24 respectively disposed in four locations of the body frame 21, a plurality of the AFs 241 are disposed in parallel on a wheeled platform 242. The AFs 241 are capable of loading a plurality of reels 2420 around which the component storage tape 243 is wound.

Before describing the configuration of the AFs 241, the component storage tape 243 will be described with reference to FIG. 7. The component storage tape 243 includes a carrier tape 2431 and a cover tape 2434. The carrier tape 2431 is a tape in which a plurality of component compartments 2433 storing components E are arranged at predetermined intervals. Also, along one end in the width direction of the carrier tape 2431, a plurality of conveying force transfer holes 2432 are arranged at predetermined intervals. The plurality of conveying force transfer holes 2432 engage with the teeth of a first sprocket 2412A and a second sprocket 2413A in the AFs 241 described later, and from first sprocket 2412A and the second sprocket 2413A receive the transfer of a conveying force for feeding the component storage tape 243. The cover tape 2434 is a tape applied to the carrier tape 2431 to cover the component compartments 2433.

As illustrated in FIG. 3, the AFs 241 are attached to a feeder attaching part 2417A provided in each component supply unit 24. More specifically, each component supply unit 24 is provided with the feeder attaching part 2417A and a reel support part 2419. The feeder attaching part 2417A is provided with a plurality of slots 2417B arranged at fixed intervals in the X-axis direction and extending parallel to each other in the Y-axis direction, and a fixed base 2417C positioned farther forward than the slots 2417B and extending in the X-axis direction. Additionally, an AF 241 is set in each slot 2417B, and each AF 241 is affixed to the fixed base 2417C. With this arrangement, the plurality of AFs 241 are disposed in parallel on the wheeled platform 242 in each component supply unit 24.

The reel support part 2419 is positioned behind and below the feeder attaching part 2417A, and supports a first reel holder 2419A and a second reel holder 2419B that rotatably support the reels 2420, such that the first and second reel holders are separated from each other in the vertical direction. The component storage tape 243 is wound around the reels 2420 supported by each of the first reel holder 2419A and the second reel holder 2419B.

Each AF 241 is provided with a feeder body 2411. Each AF 241 is affixed to the fixed base 2417C with the feeder body 2411 inserted (set) into one of the slots 2417B. The first sprocket 2412A that forms a first tape feeding part 2412 and the second sprocket 2413A that forms a second tape feeding part 2413 are rotatably supported on the feeder body 2411, such that the second sprocket 2413A is separated farther away in the Y-axis direction from the reel support part 2419 with respect to the first sprocket 2412A. The first sprocket 2412A and the second sprocket 2413A are each provided with a plurality of teeth arranged at predetermined intervals in the circumferential direction. The teeth of the first sprocket 2412A and the second sprocket 2413A are engageable with the conveying force transfer holes 2432 formed in the carrier tape 2431 of the component storage tape 243.

The component storage tape 243 wound around the reels 2420 supported by each of the first reel holder 2419A and the second reel holder 2419B is led to the first sprocket 2412A and the second sprocket 2413A while being guided by a guide roller 2418 disposed at the upper end of the reel support part 2419. The component storage tape 243, whose conveying force transfer holes 2432 are engaged with the teeth of the first sprocket 2412A and the second sprocket 2413A, is fed by the rotation of the first sprocket 2412A and the second sprocket 2413A, and the components E are picked up at a component supply position P1.

In addition, each AF 241 is provided with a tape support member 2414 detachably affixed to the rear end of the feeder body 2411, an operation input unit 2415 disposed on the rear top face of the feeder body 2411, and first and second tape detecting sensors 2416A and 2416B.

As illustrated in FIG. 3, the tape support member 2414 divides the rear end portion of a tape travel passage 2414A where the component storage tape 243 travels inside the feeder body 2411 into two upper and lower passages (an upper passage 2414AA and a lower passage 2414AB), and also supports the component storage tape 243 passing through the upper passage 2414AA from below. More specifically, the rear end portion of the tape travel passage 2414A has a shape that expands vertically going from the front to the rear. The tape support member 2414 is inserted into the tape travel passage 2414A from the rear of the feeder body 2411, and is detachably affixed to the feeder body 2411. With this arrangement, the rear end portion of the tape travel passage 2414A is divided into the upper passage 2414AA and the lower passage 2414AB by the tape support member 2414.

The first tape detecting sensor 2416A and the second tape detecting sensor 2416B are provided in a state facing the tape travel passage 2414A, and detect the presence or absence of the component storage tape 243 that passes through the tape travel passage 2414A. More specifically, the first tape detecting sensor 2416A is provided at a position farther forward than a point where the upper passage 2414AA and the lower passage 2414AB merge, facing the tape travel passage 2414A from below. On the other hand, the second tape detecting sensor 2416B is provided at a position facing the upper passage 2414AA from above, and thereby detects the presence or absence of the component storage tape 243 in the upper passage 2414AA.

The operation input unit 2415 used by a worker to feed or reverse-feed the component storage tape 243 as necessary.

The component supply operations of the AFs 241 configured like the above are as follows, described with reference to FIGS. 3 to 6. First, as preparatory work, a worker attaches a reel 2420 around which a preceding component storage tape 243 is wound to the first reel holder 2419A in the lower section of the reel support part 2419, and inserts the leading end of the component storage tape 243 wound around the reel 2420 into the upper passage 2414AA from the rear of the feeder body 2411. With this arrangement, the leading end of the preceding component storage tape 243 is supported by the tape support member 2414 while being engaged with the first sprocket 2412A. After that, the worker operates the operation input unit 2415 to input an instruction for rotating the first sprocket 2412A, which feeds the component storage tape 243 and causes the leading end of the component storage tape 243 to engage with the second sprocket 2413A.

The component supply operations of the AFs 241 are started in the state in which the above preparatory work has been finished. In each AF 241, the second sprocket 2413A rotates, thereby feeding the component storage tape 243. Note that the first sprocket 2412A is configured to spin freely, and in this case, the component storage tape 243 can be fed by causing only the second sprocket 2413A to rotate.

Next, while the preceding component storage tape 243 is being fed from the reel 2420, the worker removes the tape support member 2414 from the feeder body 2411. As illustrated in FIG. 3, when the tape support member 2414 is removed, the component storage tape 243 is displaced by its own weight to the bottom part of the tape travel passage 2414A. With this arrangement, the preceding component storage tape 243 is disengaged from the first sprocket 2412A. Because the component storage tape 243 is engaged with the second sprocket 2413A at this time, the component storage tape 243 continues to be fed by the rotation of the second sprocket 2413A even if disengaged from the first sprocket 2412A.

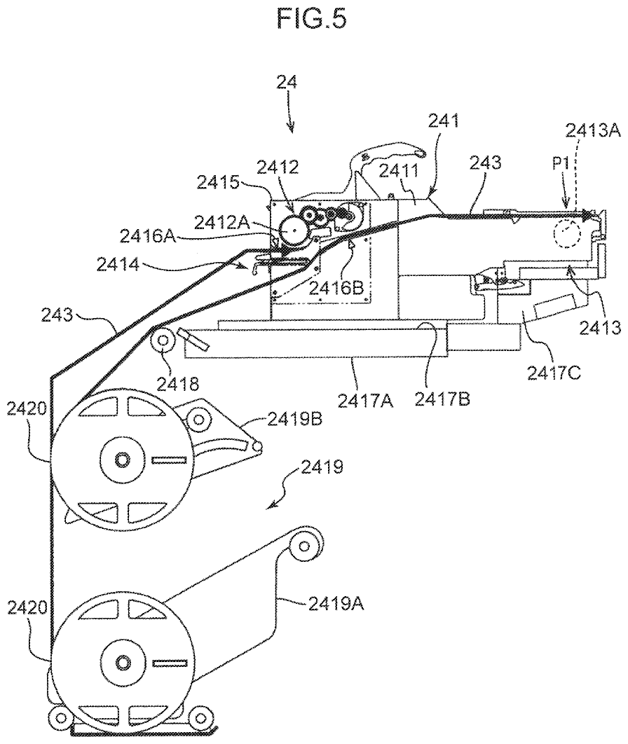

Next, while the preceding component storage tape 243 is being feed from the reel 2420, the worker loads the tape support member 2414 into the feeder body 2411, and as illustrated in FIG. 4, moves the reel 2420 around which the preceding component storage tape 243 is wound from the first reel holder 2419A in the lower section to the second reel holder 2419B in the upper section. Next, while the preceding component storage tape 243 is being fed from the reel 2420 supported by the second reel holder 2419B in the upper section, as illustrated in FIG. 5, the worker attaches a reel 2420 around which a succeeding component storage tape 243 is wound to the first reel holder 2419A in the lower section, and inserts the leading end of the component storage tape 243 into the upper passage 2414AA from the rear of the feeder body 2411. With this arrangement, the leading end of the succeeding component storage tape 243 is supported by the tape support member 2414 while being engaged with the first sprocket 2412A. Accordingly, a reel 2420 around which the succeeding component storage tape 243 is wound can be loaded before a component shortage occurs in the preceding component storage tape 243 wound around a reel 2420.

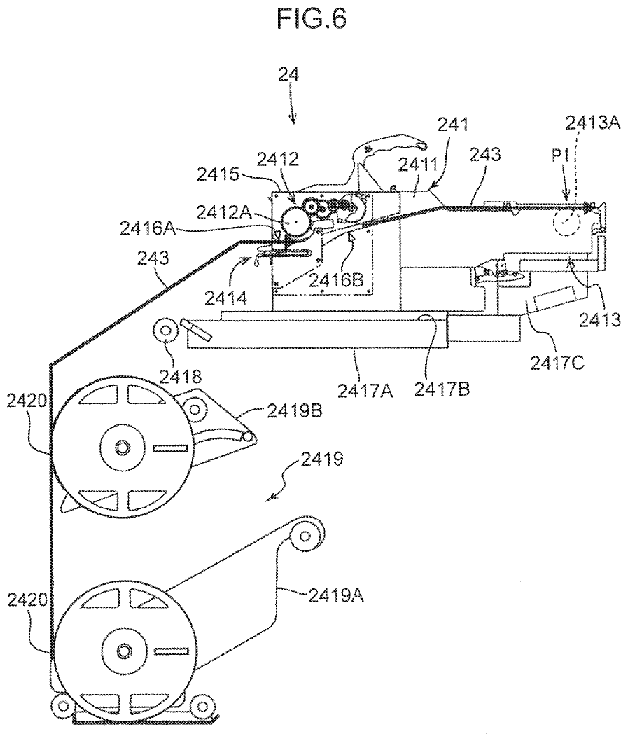

After that, the preceding component storage tape 243 is completely drawn out from the reel 2420 supported by the second reel holder 2419B in the upper section, and as illustrated in FIG. 6, when the trailing end passes through the position of the second tape detecting sensor 2416B and it is detected that no more preceding component storage tape 243 exists, the feeding of the succeeding component storage tape 243 from the reel 2420 supported by the first reel holder 2419A in the lower section is started automatically. Additionally, the worker removes the reel 2420 that has run out of components from the second reel holder 2419B in the upper section, and moves the reel 2420 around which the succeeding component storage tape 243 is wound from the first reel holder 2419A in the lower section to the second reel holder 2419B in the upper section. At this time, the worker can replenish the AF 241 with a new reel around which the component storage tape 243 is wound. The new reel replenishing the AF 241 is attached to the first reel holder 2419A in the lower section by the worker. Here, the timing of the replenishment of the new reel is not restricted to the point in time when the reel 2420 around which the preceding component storage tape 243 is wound runs out of components, but rather is specified by the component replenishment management system 3.

Note that in the state illustrated in FIG. 5, in which the preceding component storage tape 243 is fed from the reel 2420 supported by the second reel holder 2419B in the upper section and the leading end of the succeeding component storage tape 243 wound around the reel 2420 supported by the first reel holder 2419A in the lower section is inserted into the upper passage 2414AA, a new reel cannot be loaded. On the other hand, in the state illustrated in FIG. 6, in which the preceding component storage tape 243 has been completely drawn out from the reel 2420 supported by the second reel holder 2419B in the upper section and the feeding of the succeeding component storage tape 243 from the reel 2420 supported by the first reel holder 2419A in the lower section has started automatically, a new reel can be loaded.

[Configuration of Component Replenishment Management System]

The component replenishment management system 3 is a system that manages the replenishment of the reels as the component storage member for each of the plurality of AFs 241 provided in the component supply units 24. To reduce the burden of the replenishment work on the worker, the component replenishment management system 3 is capable of “batch replenishment” whereby the reel replenishment work is performed all at once for AFs 241 that can be replenished with reels at the same replenishment timing.

### First Embodiment

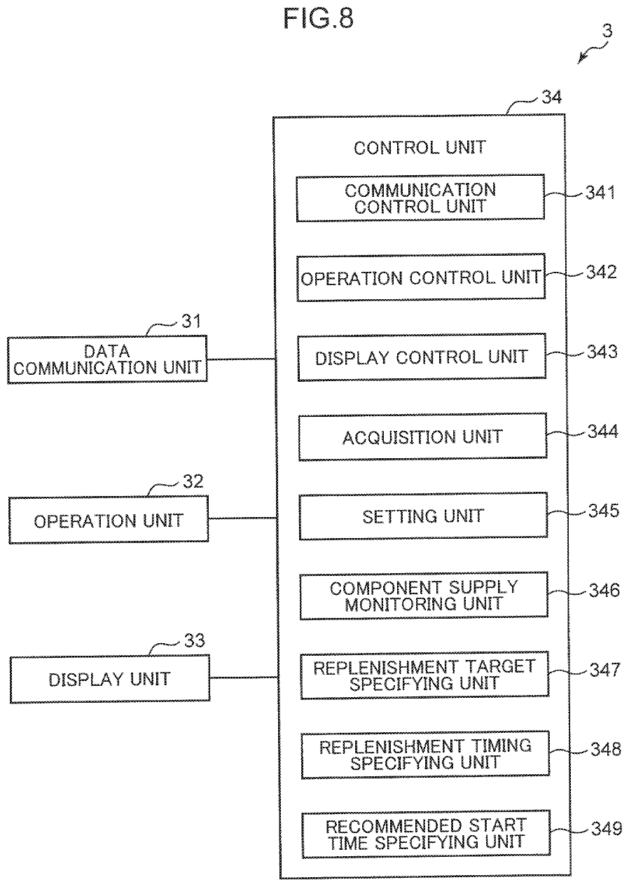

FIG. 8 is a block diagram illustrating a configuration of the component replenishment management system 3 according to a first embodiment. Hereinafter, the component replenishment management system 3 according to the first embodiment will be referred to as the “first component replenishment management system 3”. As illustrated in FIG. 1, in the first component replenishment management system 3, a mounter operation management device 4, a production plan management device 5, and a setup management device 6 are communicably connected to each other. In addition, the first component replenishment management system 3 includes a microcontroller for example, and as illustrated in FIG. 8, is provided with a data communication unit 31, an operation unit 32, a display unit 33, and a control unit 34.

The operation unit 32 is provided with elements such as a touch panel, a keypad, a start key, and a settings key, and receives worker operations and various settings with respect to the first component replenishment management system 3. The display unit 33 displays specification result information generated by a unit such as a replenishment target specifying unit 347 of the control unit 34 described later. The data communication unit 31 is an interface circuit for achieving data communication with the mounter operation management device 4, the production plan management device 5, and the setup management device 6. The data communication unit 31 acquires information transmitted from the mounter operation management device 4, the production plan management device 5, and the setup management device 6, and supplies the acquired information to the control unit 34. Additionally, the control unit 34 supplies the data communication unit 31 with specification result information generated by a unit such as the replenishment target specifying unit 347, and the data communication unit 31 transmits (outputs) the specification result information to the mounter operation management device 4, the production plan management device 5, and the setup management device 6.

At this point, the mounter operation management device 4, the production plan management device 5, and the setup management device 6 communicably connected to the first component replenishment management system 3 will be described.

The mounter operation management device 4 is installed near the mounted substrate production line where the mounters 2 are disposed, and is a device for managing the mounting operations by the mounters 2. The mounter operation management device 4 contains a microcontroller, for example. A worker on the production line operates the mounter operation management device 4 to control the mounting operations by the mounters 2. In accordance with an operation by the worker on the production line, the mounter operation management device 4 transmits component remaining count information related to the total number of remaining components E stored in the component storage tape 243 wound around the reels 2420 respectively loaded into the first reel holder 2419A and the second reel holder 2419B in each AF 241 to the first component replenishment management system 3. The component remaining count information transmitted from the mounter operation management device 4 is input into the first component replenishment management system 3 through the data communication unit 31. Note that the component remaining count information may also be transmitted from the setup management device 6 described later. The mounter operation management device 4 also receives the input of specification result information generated by a unit such as the replenishment target specifying unit 347 described later, which is transmitted from the first component replenishment management system 3 through the data communication unit 31. The worker on the production line performs the work of replenishing the AFs 241 with reels based on the specification result information input into the mounter operation management device 4.

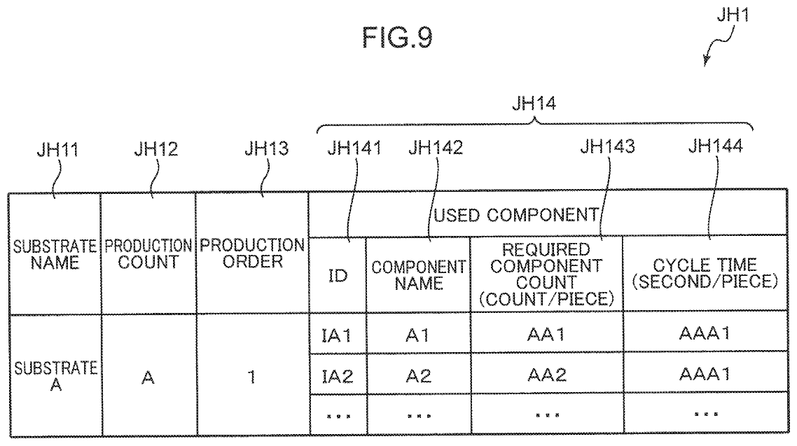

The production plan management device 5 is a device for managing a mounted substrate production plan followed by the mounters 2. The production plan management device 5 contains a microcontroller, for example. In accordance with an operation by a worker who drafts a production plan, the production plan management device 5 transmits production plan information related to a mounted substrate production plan to the first component replenishment management system 3. FIG. 9 is a table for explaining production plan information JH1 that is transmitted from the production plan management device 5 and input into the first component replenishment management system 3. The production plan information JH1 is information that includes at least required component count information JH143 and cycle time information JH144. The required component count information JH143 is information related to the required number of components E needed to produce a single mounted substrate (parts per board). The cycle time information JH144 is information related to the time taken to mount the components E during the production of a single mounted substrate (seconds per board).

Specifically, as illustrated in FIG. 9, the production plan information JH1 is information associating substrate information JH11 for specifying a substrate P submitted to produce a mounted substrate, production count information JH12 expressing the number of produced mounted substrates, production order information JH13 expressing the production order of the mounted substrate, and used component information JH14 related to the components E used during the production of the mounted substrate. Note that the used component information JH14 is information associating component identification information JH141 for identifying each component E, component type specification information JH142 for specifying each component E, the required component count information JH143, and the cycle time information JH144. The required component count information JH143 is set for each component identified by the component identification information JH141. Also, the cycle time information JH144 is set for each substrate specified by the substrate information JH11. Described with reference to FIG. 9, the cycle time expressed by the cycle time information JH144 is the same value (“AAA1”) for each of the components (“IA1” and “IA2”) identified by the component identification information JH141 with respect to one “substrate A” specified by the substrate information JH11. If the substrate is different, values corresponding to the different substrate are set.

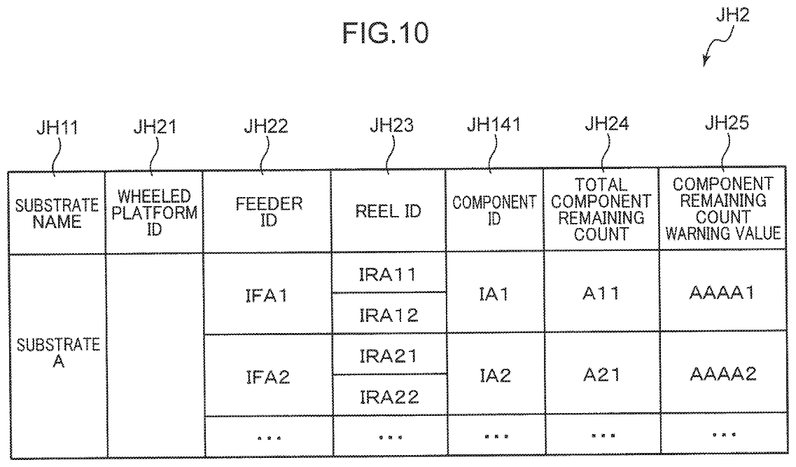

The setup management device 6 is a device for managing setup work required for production before the production of the mounted substrate by the mounters 2. The setup management device 6 contains a microcontroller for example, and outputs setup information required for setup work. A worker performs setup work based on the output information from the setup management device 6. In addition, the setup management device 6 transmits the setup information to the first component replenishment management system 3 in accordance with an operation by the worker. FIG. 10 is a table for explaining setup information JH2 that is transmitted from the setup management device 6 and input into the first component replenishment management system 3. The setup information JH2 may also be information that includes component remaining count information JH24. As described earlier, the component remaining count information JH24 is information related to the total number of remaining components E stored in the component storage tape 243 wound around the reels 2420 respectively loaded into the first reel holder 2419A and the second reel holder 2419B in each AF 241, and is transmitted from the mounter operation management device 4 in the present embodiment.

Specifically, as illustrated in FIG. 10, the setup information JH2 is information associating the substrate information JH11, wheeled platform identification information JH21, feeder identification information JH22, reel identification information JH23, the component identification information JH141, the component remaining count information JH24, and component remaining count warning value information JH25. The wheeled platform identification information JH21 is information for identifying the wheeled platform 242 on which the plurality of AFs 241 are disposed in parallel in the component supply units 24. The feeder identification information JH22 is information for identifying each of the AFs 241. The reel identification information JH23 is information for identifying each of the reels 2420 respectively loaded into the first reel holder 2419A and the second reel holder 2419B in the AFs 241. The component remaining count warning value information JH25 is information indicating that the total number of remaining components expressed by the component remaining count information JH24 is a predetermined value (component remaining count warning value) at which a warning is to be issued before there is a shortage of the components E stored in the component storage tape 243 wound around the reels 2420 respectively loaded into the first reel holder 2419A and the second reel holder 2419B.

The control unit 34 of the first component replenishment management system 3 is provided with components such as a central processing unit (CPU), read-only memory (ROM) that stores a control program, and random access memory (RAM) used as a work area by the CPU. The control unit 34 controls the data communication unit 31, the operation unit 32, and the display unit 33 by having the CPU execute the control program stored in the ROM, and also generates various specification result information related to the replenishment of the reels for each of the plurality of AFs 241 provided in the component supply units 24. As illustrated in FIG. 8, the control unit 34 includes a communication control unit 341, an operation control unit 342, a display control unit 343, an acquisition unit 344, a setting unit 345, a component supply monitoring unit 346, a replenishment target specifying unit 347, a replenishment timing specifying unit 348, and a recommended start time specifying unit 349.

The communication control unit 341 controls data communication with the mounter operation management device 4, the production plan management device 5, and the setup management device 6 by the data communication unit 31. The operation control unit 342 controls the operation unit 32. The display control unit 343 controls information display operations by the display unit 33.

(Control Operations Related to Component Replenishment in First Component Replenishment Management System)

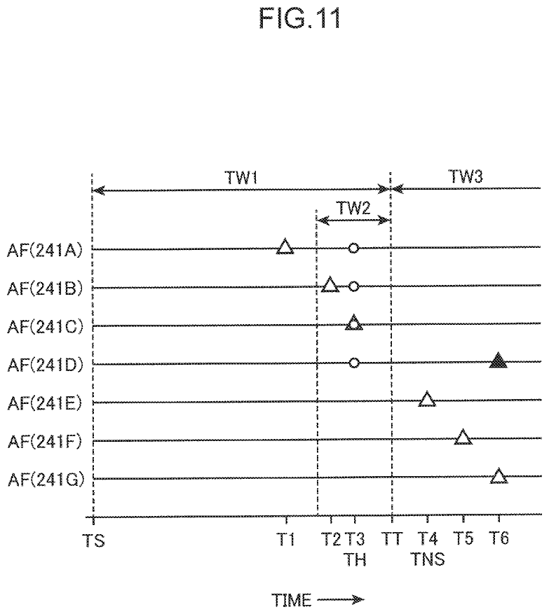

The configuration of the control unit 34 will be described with reference to FIG. 11 in addition to FIG. 8. FIG. 11 is a chart for explaining control operations by the first component replenishment management system 3. FIG. 11 illustrates an example of supplying components from the seven AFs 241A, 241B, 241C, 241D, 241E, 241F, and 241G among the plurality of AFs 241 disposed in parallel on the wheeled platform 242 of each component supply unit 24, and producing the mounted substrate. Note that it is assumed that tape feeders other than the AFs 241, namely splicing feeders, are also disposed in parallel in the component supply units 24. As described earlier, a splicing feeder is configured such that a single reel is loaded. In a splicing feeder, in order to switch from a preceding component storage tape to a succeeding component storage tape before the preceding component storage tape is fed completely from the reel and a component shortage occurs, it is necessary to perform splicing work to join the trailing end of the preceding component storage tape to the leading end of the succeeding component storage tape. Additionally, the AFs 241A, 241B, 241C, 241D, 241E, 241F, and 241G may be disposed in the component supply units 24 of the same mounter 2 or in the component supply units 24 of a plurality of different mounters 2.

The acquisition unit 344 acquires a management start time TS that expresses a start time of managing reel replenishment for each of the plurality of AFs 241A, 241B, 241C, 241D, 241E, 241F, and 241G. The acquisition unit 344 may acquire the time of starting the production of the mounted substrate as the management start time TS, or in the case where command information giving a command to start management is input through the operation unit 32, the acquisition unit 344 may acquire the time when the command information is input as the management start time TS. In the present embodiment, the acquisition unit 344 acquires the time when the command information is input through the operation unit 32 as the management start time TS.

The setting unit 345 sets a specified period TW1 until a specified time TT after a predetermined specified length of time has elapsed from the management start time TS. Additionally, within the specified period TW1, the setting unit 345 sets a predetermined management period TW2 such that the specified time TT coincides with the latest time of the management period TW2 (hereinafter referred to as the “latest time”). The specified length of time that the setting unit 345 uses when setting the specified period TW1 and the time interval of the management period TW2 are input by a worker through the operation unit 32. The specified length of time is set to any length of time, such as 60 minutes, for example. The specified length of time may also be set to a length of time such that the time when splicing work is estimated to occur for a splicing feeder is near the specified time TT. In this case, although details will be described later, the worker is able to perform the splicing work for the splicing feeder together with the reel replenishment work for the AFs 241 within the management period TW2 based on the specified time TT.

The component supply monitoring unit 346 monitors the supply status of the components E in each of the plurality of AFs 241A, 241B, 241C, 241D, 241E, 241F, and 241G. The component supply monitoring unit 346 specifies, for each of the plurality of AFs 241A, 241B, 241C, 241D, 241E, 241F, and 241G, a replenishment possibility time at which the corresponding AF 241 can be replenished with a new reel. The replenishment possibility time is the time at which the reel 2420 around which the preceding component storage tape 243 used to supply preceding components is wound will run out of components from among the reels 2420 respectively loaded into the first reel holder 2419A and the second reel holder 2419B in each of the plurality of AFs 241A, 241B, 241C, 241D, 241E, 241F, and 241G. When the preceding reel 2420 runs out of components, replenishment with a new reel becomes possible.

Also, the component supply monitoring unit 346 specifies a remaining count warning time for each of the plurality of AFs 241A, 241B, 241C, 241D, 241E, 241F, and 241G. The remaining count warning time is the time at which the total number of remaining components in the component storage tape 243 wound around the reels 2420 respectively loaded into the first reel holder 2419A and the second reel holder 2419B will reach the predetermined component remaining count warning value.

The component supply monitoring unit 346 specifies the replenishment possibility time and the remaining count warning time on the basis of information supplied to the control unit 34 from the data communication unit 31, namely the component remaining count information JH24 from the mounter operation management device 4 (or the setup management device 6), the production plan information JH1 from the production plan management device 5, and the setup information JH2 from the setup management device 6.

Specifically, the component supply monitoring unit 346 first subtracts the remaining number of components in the reel 2420 around which the succeeding component storage tape 243 is wound from the total number of remaining components expressed by the component remaining count information JH24, and computes the number of remaining components in the reel 2420 around which the preceding component storage tape 243 is wound. Additionally, the component supply monitoring unit 346 computes the number of components used per second by dividing the required number of each component identified by the component identification information JH141 needed to produce a single mounted substrate, expressed by the required component count information JH143, by the mounting time, specified by the cycle time information JH144, of each component during the production of a single mounted substrate for each substrate specified by the substrate information JH11. Thereafter, the component supply monitoring unit 346 computes the replenishment possibility time by dividing the remaining number of components in the reel 2420 around which the preceding component storage tape 243 is wound by the number of components used per second. On the other hand, the component supply monitoring unit 346 computes the remaining count warning time by subtracting the component remaining count warning value expressed by the component remaining count warning value information JH25 from the total number of remaining components expressed by the component remaining count information JH24, and dividing the resulting number of components by the number of components used per second.

Incidentally, the total number of remaining components expressed by the component remaining count information JH24 is decremented every time a component is picked up by the head unit 25. Although details will be described later, when the reel 2420 around which the preceding component storage tape 243 is wound runs out of components and the AFs 241A, 241B, 241C, 241D, 241E, 241F, and 241G are replenished with a new reel, the total number of remaining components is updated by adding the number of components stored in the component storage tape 243 wound around the new reel (initial set number) to the total number of remaining components that changes every time a component is picked up by the head unit 25. The number of components stored in the component storage tape 243 wound around the new reel (initial set number) is stored for each component identified by the component identification information JH141 in a location such as the ROM of the control unit 34. Note that in the case where a reel around which partially used component storage tape 243 is wound is used for replenishment as the new reel, the initial set number stored in the ROM or the like of the control unit 34 is overwritten by the actual number of components stored in the component storage tape 243.

With regard to the example illustrated in FIG. 11, the replenishment possibility time and the remaining count warning time specified by the component supply monitoring unit 346 in association with each of the plurality of AFs 241A, 241B, 241C, 241D, 241E, 241F, and 241G are described as follows.

A replenishment possibility time T1 is specified for the AF 241A. The replenishment possibility time T1 of the AF 241A is a time earlier than the specified time TT and also earlier than the earliest time of the management period TW2 (hereinafter referred to as the “earliest time”), and is included in a time window before the earliest time of the management period TW2 within the specified period TW1. The remaining count warning time of the AF 241A is not indicated in FIG. 11, but is included in a time window TW3 after the specified time TT.

A replenishment possibility time T2 is specified for the AF 241B. The replenishment possibility time T2 of the AF 241B is a time earlier than the specified time TT and also later than the earliest time of the management period TW2, and is included in the management period TW2. The remaining count warning time of the AF 241B is not indicated in FIG. 11, but is included in a time window TW3 after the specified time TT.

A replenishment possibility time T3 is specified for the AF 241C. The replenishment possibility time T3 of the AF 241C is a time earlier than the specified time TT and also later than the earliest time of the management period TW2, is included in the management period TW2, and is a time later than the replenishment possibility time T2 of the AF 241B. The remaining count warning time of the AF 241C is not indicated in FIG. 11, but is included in a time window TW3 after the specified time TT.

The replenishment possibility time of the AF 241D is not illustrated in FIG. 11. The replenishment possibility time of the AF 241D is a time earlier than the specified time TT and also earlier than the management start time TS, and is included in a time window before the management start time TS. A remaining count warning time T6 is specified for the AF 241D. The remaining count warning time T6 of the AF 241D is a time later than the specified time TT, and is included in the time window TW3 after the specified time TT.

A replenishment possibility time T4 is specified for the AF 241E. The replenishment possibility time T4 of the AF 241E is a time later than the specified time TT, and is included in the time window TW3 after the specified time TT. The remaining count warning time of the AF 241E is not illustrated in FIG. 11. The remaining count warning time of the AF 241E is a time later than the replenishment possibility time T4, and is included in the time window TW3 after the specified time TT.

A replenishment possibility time T5 is specified for the AF 241F. The replenishment possibility time T5 of the AF 241F is a time later than the specified time TT, and is included in the time window TW3 after the specified time TT. The replenishment possibility time T5 of the AF 241F is a time later than the replenishment possibility time T4 of the AF 241E. The remaining count warning time of the AF 241F is not illustrated in FIG. 11. The remaining count warning time of the AF 241F is a time later than the replenishment possibility time T5, and is included in the time window TW3 after the specified time TT.

A replenishment possibility time T6 is specified for the AF 241G. The replenishment possibility time T6 of the AF 241G is a time later than the specified time TT, and is included in the time window TW3 after the specified time TT. The replenishment possibility time T6 of the AF 241G is a time later than the replenishment possibility time T5 of the AF 241F. The remaining count warning time of the AF 241G is not illustrated in FIG. 11. The remaining count warning time of the AF 241G is a time later than the replenishment possibility time T6, and is included in the time window TW3 after the specified time TT.

Next, the replenishment target specifying unit 347 specifies an AF 241 whose replenishment possibility time is a time earlier than the specified time TT as a component replenishment target device to be replenished with a new reel in the management period TW2 within the specified period TW1. In the example illustrated in FIG. 11, the replenishment target specifying unit 347 specifies all of the AFs 241A, 241B, 241C, and 241D whose replenishment possibility time is a time earlier than the specified time TT as component replenishment target devices.

In the first component replenishment management system 3, all of the AFs 241A, 241B, 241C, and 241D that can be replenished with a new reel in the management period TW2 within the specified period TW1 based on the specified time TT are treated as component replenishment target devices by the replenishment target specifying unit 347. With this arrangement, “batch replenishment” becomes possible in which the reel replenishment work is performed all at once by a worker for the AFs 241A, 241B, 241C, and 241D that can be replenished with a new reel in the management period TW2 within the specified period TW1. For this reason, the worker is able to perform the “batch replenishment” of new reels by treating the specified time TT that serves as the basis of the specified period TW1 as an estimate of the work start time for the replenishment work. Consequently, the frequency at which the worker goes to the mounters 2 where the AFs 241 are installed can be reduced, and the burden of replenishment work imposed on the worker can be reduced.

Next, the replenishment timing specifying unit 348 specifies the same new reel replenishment timing TH in the management period TW2 within the specified period TW1 for the AFs 241A, 241B, 241C, and 241D specified as component replenishment target devices by the replenishment target specifying unit 347. With this arrangement, the worker is able to perform the work of replenishing the AFs 241A, 241B, 241C, and 241D specified as the component replenishment target devices with new reels at the same replenishment timing TH.

More specifically, among the AFs 241A, 241B, 241C, and 241D specified as the component replenishment target devices by the replenishment target specifying unit 347, the replenishment timing specifying unit 348 recognizes a target device of interest whose replenishment possibility time is a time later than the earliest time of the management period TW2. In the example illustrated in FIG. 11, the AFs 241B and 241C whose respective replenishment possibility times T2 and T3 are later than the earliest time of the management period TW2 are recognized as target devices of interest. Between the replenishment possibility time T2 and the replenishment possibility time T3 corresponding to the AFs 241B and 241C treated as the target devices of interest, the replenishment timing specifying unit 348 specifies the replenishment possibility time T3 that occurs at the latest time as a replenishment possibility time of interest. In addition, the replenishment timing specifying unit 348 specifies any time between the replenishment possibility time T3 specified as the replenishment possibility time of interest and the specified time TT within the specified period TW1 as the replenishment timing TH.

The time window between the replenishment possibility time T3 as the replenishment possibility time of interest and the specified time TT is a time window in which all of the AFs 241A, 241B, 241C, and 241D specified by the replenishment target specifying unit 347 as the component replenishment target devices whose replenishment possibility time is a time earlier than the specified time TT can be replenished with new reels. In other words, the time window between the replenishment possibility time T3 as the replenishment possibility time of interest and the specified time TT is a time window in which “batch replenishment” is possible, such that the work of replenishing the AFs 241A, 241B, 241C, and 241D treated as the component replenishment target devices with new reels is performed all at once. The replenishment timing specifying unit 348 specifies any such time between the replenishment possibility time T3 as the replenishment possibility time of interest and the specified time TT as the replenishment timing TH at which to replenish the AFs 241A, 241B, 241C, and 241D treated as the component replenishment target devices with reels. With this arrangement, the worker is able to perform the work of replenishing the AFs 241A, 241B, 241C, and 241D treated as the component replenishment target devices with reels at any replenishment timing TH between the replenishment possibility time T3 as the replenishment possibility time of interest and the specified time TT.

In the example illustrated in FIG. 11, the replenishment timing specifying unit 348 specifies the replenishment possibility time T3 as the replenishment possibility time of interest in the management period TW2 within the specified period TW1 as the replenishment timing TH. As described earlier, the time window between the replenishment possibility time T3 as the replenishment possibility time of interest and the specified time TT is a time window in which “batch replenishment” is possible, such that the work of replenishing the AFs 241A, 241B, 241C, and 241D treated as the component replenishment target devices with new reels is performed all at once. The replenishment possibility time T3 as the replenishment possibility time of interest is the earliest time within the time window at which “batch replenishment” is possible. By treating the replenishment possibility time T3 as the replenishment possibility time of interest as the reel replenishment timing TH for the AFs 241A, 241B, 241C, and 241D treated as the component replenishment target devices, the worker is able to perform “batch replenishment” in a state with time to spare.

Next, the recommended start time specifying unit 349 specifies a recommended next start time TNS recommended as the start time for replenishment management next time in the time window TW3 after the specified time TT. In the example illustrated in FIG. 11, the recommended start time specifying unit 349 specifies the start time for replenishment management next time with respect to the remaining AFs 241E, 241F, and 241G other than the AFs 241A, 241B, 241C, and 241D treated as the component replenishment target devices from among the plurality of AFs 241A, 241B, 241C, 241D, 241E, 241F, and 241G.

The recommended start time specifying unit 349 specifies the earliest time T4 among the replenishment possibility times T4, T5, and T6 corresponding to the remaining AFs 241E, 241F, and 241G other than the component replenishment target devices as the recommended next start time TNS. Note that the recommended start time specifying unit 349 may also be configured to specify the specified time TT as the recommended next start time TNS. The recommended start time specifying unit 349 generates specification result information expressing the specification result of the recommended next start time TNS. The specification result information is displayed on the display unit 33 controlled by the display control unit 343. The specification result information is also supplied to the data communication unit 31, and is transmitted from the data communication unit 31 controlled by the communication control unit 341 to the mounter operation management device 4, a mobile terminal device carried by a worker, or a component warehouse terminal device disposed in a component warehouse where reels and the like to load into the AFs 241 are kept. The mounter operation management device 4, the mobile terminal device, and the component warehouse terminal device display the input specification result information. By checking the specification result information displayed on the display unit 33 or the like, a worker is able to grasp the recommended next start time TNS as the start time for replenishment management next time after the specified time TT. After grasping the recommended next start time TNS, the worker is able to predict the timing of the next replenishment work for the AFs 241E, 241F, and 241G by adding the predetermined specified length of time to the recommended next start time TNS. This arrangement makes it easy for the worker to create a plan for replenishment work.

When command information giving a command to start management for the AFs 241E, 241F, and 241G is input through the operation unit 32 by the worker who has checked the specification result information and grasped the recommended next start time TNS, the acquisition unit 344 acquires the time when the command information is input as the management start time. When the management start time for the AFs 241E, 241F, and 241G according to the command information is acquired by the acquisition unit 344 through the operation unit 32, the operations described above by each of the setting unit 345, the component supply monitoring unit 346, the replenishment target specifying unit 347, the replenishment timing specifying unit 348, and the recommended start time specifying unit 349 are repeated. Note that the acquisition unit 344 may also acquire the recommended next start time TNS automatically as the management start time for starting the reel replenishment management for the AFs 241E, 241F, and 241G. When the recommended next start time TNS is acquired automatically as the management start time for the AFs 241E, 241F, and 241G by the acquisition unit 344, the operations described above by each of the setting unit 345, the component supply monitoring unit 346, the replenishment target specifying unit 347, the replenishment timing specifying unit 348, and the recommended start time specifying unit 349 are repeated automatically.

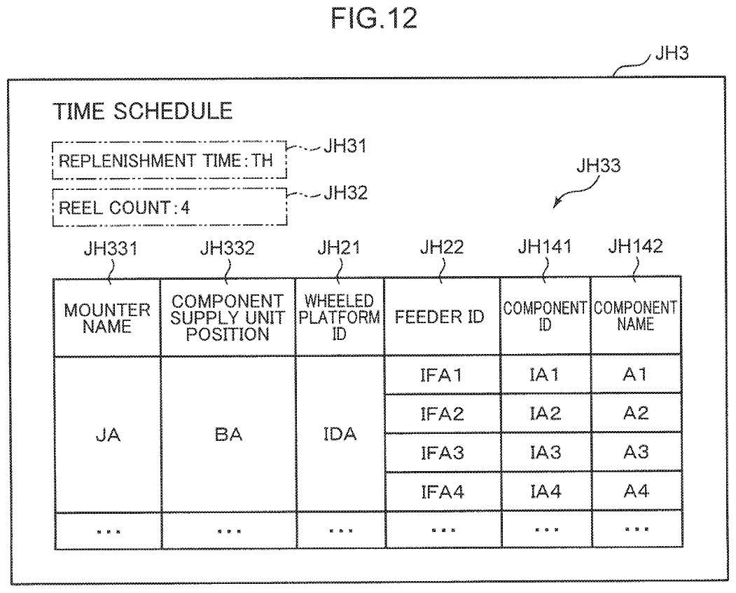

The replenishment target specifying unit 347 generates replenishment specification result information expressing the specification result of the component replenishment target device(s). Note that information related to the replenishment timing TH specified by the replenishment timing specifying unit 348 and information related to the recommended next start time TNS specified by the recommended start time specifying unit 349 may also be added to the replenishment specification result information generated by the replenishment target specifying unit 347. FIG. 12 is a diagram for explaining replenishment specification result information JH3 generated by the replenishment target specifying unit 347 of the first component replenishment management system 3.

The replenishment specification result information JH3 is information including replenishment timing information JH31, replenishment count information JH32, and replenishment component information JH33. The replenishment timing information JH31 is information expressing the specification result of the replenishment timing TH by the replenishment timing specifying unit 348. The replenishment count information JH32 is information expressing the total number of new reels to be used to replenish the AFs 241A, 241B, 241C, and 241D treated as the component replenishment target devices specified by the replenishment target specifying unit 347.

The replenishment component information JH33 is information related to the new reels to be used to replenish the AFs 241A, 241B, 241C, and 241D treated as the component replenishment target devices specified by the replenishment target specifying unit 347. As illustrated in FIG. 12, the replenishment component information JH33 is information associating mounter type specification information JH331, component supply unit position information JH332, the wheeled platform identification information JH21, the feeder identification information JH22, the component identification information JH141, and the component type specification information JH142. The mounter type specification information JH331 is information for specifying the mounter 2 where the AFs 241A, 241B, 241C, and 241D are attached. The component supply unit position information JH332 is information for specifying the disposed position of the component supply unit 24 where the AFs 241A, 241B, 241C, and 241D are provided in the mounter 2.

The replenishment specification result information JH3 is displayed on the display unit 33 controlled by the display control unit 343. The replenishment specification result information JH3 is also supplied to the data communication unit 31 and transmitted to the mounter operation management device 4 from the data communication unit 31 controlled by the communication control unit 341. Based on the replenishment specification result information JH3 input into the mounter operation management device 4, a worker on the production line is able to perform the work of replenishing the AFs 241 with reels.

(Special Control Operations in First Component Replenishment Management System)

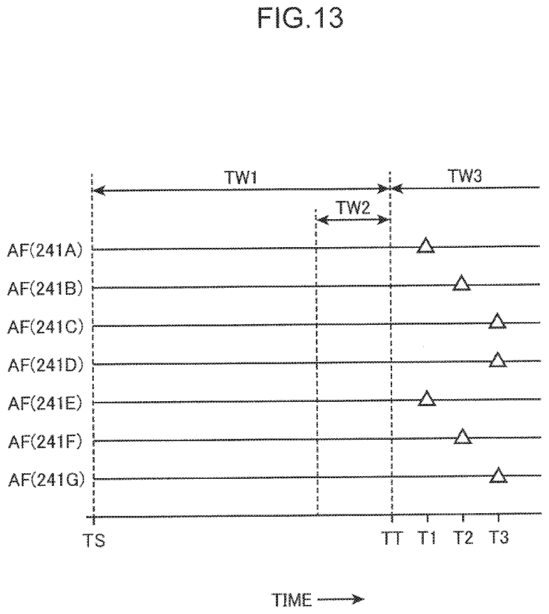

As illustrated in FIG. 13, in some cases, all of the replenishment possibility times T1, T2, and T3 for each of the plurality of AFs 241A, 241B, 241C, 241D, 241E, 241F, and 241G specified by the component supply monitoring unit 346 are times later than the specified time TT. In such cases, the replenishment target specifying unit 347 determines that a component replenishment target device to target for replenishment with a new reel does not exist within the management period TW2 based on the specified time TT. Additionally, the replenishment target specifying unit 347 generates message information such as “A component replenishment target device does not exist.” as the replenishment specification result information. The message information is displayed on the display unit 33 and also transmitted to the mounter operation management device 4 through the data communication unit 31. Based on the message information, a worker on the production line is able to grasp that there is no replenishment work to perform at the specified time TT as an estimate.

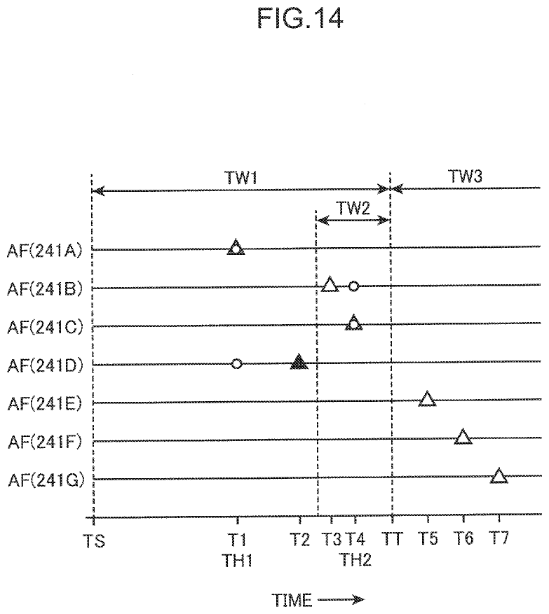

Also, as illustrated in FIG. 14, in some cases, AFs 241 whose remaining count warning time specified by the component supply monitoring unit 346 is earlier than the management period TW2 exist. With regard to the example illustrated in FIG. 14, the replenishment possibility time and the remaining count warning time specified by the component supply monitoring unit 346 in association with each of the plurality of AFs 241A, 241B, 241C, 241D, 241E, 241F, and 241G are described as follows.

A replenishment possibility time T1 is specified for the AF 241A. The replenishment possibility time T1 of the AF 241A is a time earlier than the specified time TT and also earlier than the earliest time of the management period TW2, and is included in a time window before the earliest time of the management period TW2 within the specified period TW1. The remaining count warning time of the AF 241A is not indicated in FIG. 14, but is included in a time window TW3 after the specified time TT.

A replenishment possibility time T3 is specified for the AF 241B. The replenishment possibility time T3 of the AF 241B is a time earlier than the specified time TT and also later than the earliest time of the management period TW2, and is included in the management period TW2. The remaining count warning time of the AF 241B is not indicated in FIG. 14, but is included in a time window TW3 after the specified time TT.

A replenishment possibility time T4 is specified for the AF 241C. The replenishment possibility time T4 of the AF 241C is a time earlier than the specified time TT and also later than the earliest time of the management period TW2, is included in the management period TW2, and is a time later than the replenishment possibility time T3 of the AF 241B. The remaining count warning time of the AF 241C is not indicated in FIG. 14, but is included in a time window TW3 after the specified time TT.

The replenishment possibility time of the AF 241D is not illustrated in FIG. 14. The replenishment possibility time of the AF 241D is a time earlier than the specified time TT and also earlier than the management start time TS, and is included in a time window before the management start time TS. A remaining count warning time T2 is specified for the AF 241D. The remaining count warning time T2 of the AF 241D is a time earlier than the earliest time of the management period TW2.

A replenishment possibility time T5 is specified for the AF 241E. The replenishment possibility time T5 of the AF 241E is a time later than the specified time TT, and is included in the time window TW3 after the specified time TT. The remaining count warning time of the AF 241E is not illustrated in FIG. 14. The remaining count warning time of the AF 241E is a time later than the replenishment possibility time T5, and is included in the time window TW3 after the specified time TT.

A replenishment possibility time T6 is specified for the AF 241F. The replenishment possibility time T6 of the AF 241F is a time later than the specified time TT, and is included in the time window TW3 after the specified time TT. The remaining count warning time of the AF 241F is not illustrated in FIG. 14. The remaining count warning time of the AF 241F is a time later than the replenishment possibility time T6, and is included in the time window TW3 after the specified time TT.

A replenishment possibility time T7 is specified for the AF 241G. The replenishment possibility time T7 of the AF 241G is a time later than the specified time TT, and is included in the time window TW3 after the specified time TT. The remaining count warning time of the AF 241G is not illustrated in FIG. 14. The remaining count warning time of the AF 241G is a time later than the replenishment possibility time T7, and is included in the time window TW3 after the specified time TT.

In this way, in the case where the remaining count warning time T2 earlier than the management period TW2 is included within the specified period TW1, the replenishment target specifying unit 347 specifies the AFs 241A, 241B, 241C, and 241D whose replenishment possibility time is earlier than the specified time TT while distinguishing between first component replenishment target devices and second component replenishment target devices. The replenishment target specifying unit 347 specifies the AF 241A with the replenishment possibility time T1 earlier than the remaining count warning time T2 and the AF 241D corresponding to the remaining count warning time T2 as the first component replenishment target devices. Also, the replenishment target specifying unit 347 specifies the AFs 241B and 241C corresponding to the replenishment possibility times T3 and T4 within the management period TW2 as the second component replenishment target devices.

The replenishment timing specifying unit 348 specifies the same new reel first replenishment timing TH1 in a time window earlier than the remaining count warning time T2 for the AFs 241A and 241D specified as the first component replenishment target devices by the replenishment target specifying unit 347. With this arrangement, in the time window earlier than the remaining count warning time T2, a worker is able to perform the work of replenishing the AFs 241A and 241D specified as the first component replenishment target devices with new reels at the same first replenishment timing TH1. In addition, the replenishment timing specifying unit 348 specifies the same new reel second replenishment timing TH2 within the management period TW2 for the AFs 241B and 241C specified as the second component replenishment target devices by the replenishment target specifying unit 347. With this arrangement, a worker is able to perform the work of replenishing the AFs 241B and 241C specified as the second component replenishment target devices with new reels at the same second replenishment timing TH2.

As illustrated in FIG. 14, in the case where the remaining count warning time T2 earlier than the management period TW2 is included within the specified period TW1, the replenishment target specifying unit 347 generates message information such as “Urgent replenishment work is necessary in the time window earlier than the management period based on the specified time.” as the replenishment specification result information. The message information is displayed on the display unit 33 and also transmitted to the mounter operation management device 4 through the data communication unit 31. Based on the message information, a worker on the production line is able to grasp that urgent replenishment work is necessary at the first replenishment timing TH1 earlier than the management period TW2, in addition to the replenishment work at the second replenishment timing TH2 within the management period TW2.

(Modification of Control Operations by First Component Replenishment Management System)

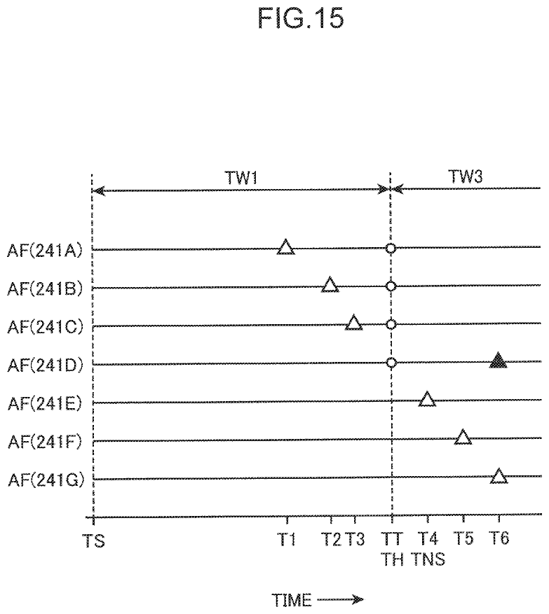

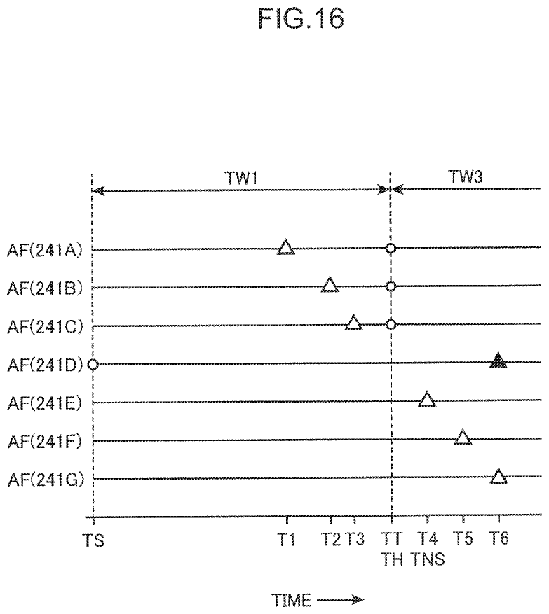

FIGS. 15 and 16 are charts for explaining a first modification of replenishment timing specifying operations by the replenishment timing specifying unit 348 of the first component replenishment management system 3. The replenishment timing specifying unit 348 may also be configured to specify the specified time TT within the specified period TW1 as the same replenishment timing TH for the AFs 241A, 241B, 241C, and 241D specified as component replenishment target devices by the replenishment target specifying unit 347. Note that in the case where the replenishment timing specifying unit 348 performs an operation of specifying the specified time TT as the replenishment timing TH, the setting unit 345 does not have to set the management period TW2 described earlier, and may simply set the specified period TW1 only. Also, the setting unit 345 may set the management period TW2 described earlier, and in the case where the replenishment timing specifying unit 348 performs an operation of specifying the specified time TT as the replenishment timing TH, the setting unit 345 may be configured to set the time interval of the management period TW2 to “0 (zero)”. A worker is able to perform the work of replenishing the AFs 241A, 241B, 241C, and 241D treated as the component replenishment target devices with reels by taking the specified time TT that serves as the basis of the specified period TW1 as the replenishment timing TH.

Additionally, in the case where an AF 241 that can be replenished with a new reel at the management start time TS exists, the replenishment timing specifying unit 348 may be configured to set the new reel replenishment timing for the AF 241 to the management start time TS. In the example illustrated in FIG. 16, the replenishment timing specifying unit 348 sets the management start time TS as the replenishment timing with respect to the AF 241D that can be replenished with a new reel at the management start time TS.

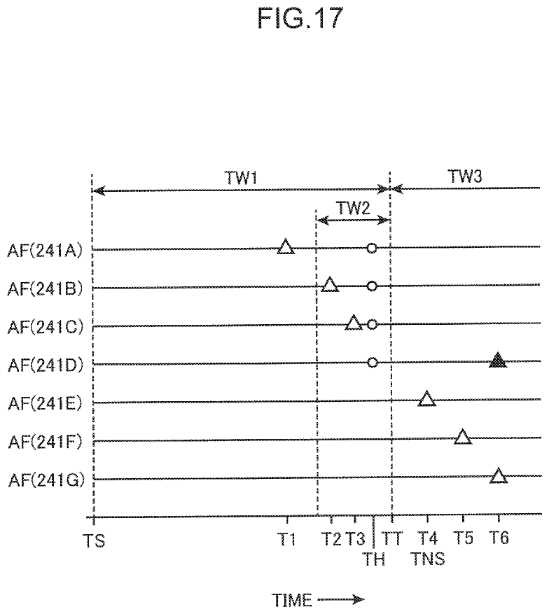

FIG. 17 is a chart for explaining a second modification of replenishment timing specifying operations by the replenishment timing specifying unit 348 of the first component replenishment management system 3. Among the AFs 241A, 241B, 241C, and 241D specified as the component replenishment target devices by the replenishment target specifying unit 347, the replenishment timing specifying unit 348 recognizes a target device of interest whose replenishment possibility time is a time later than the earliest time of the management period TW2. In the example illustrated in FIG. 17, the AFs 241B and 241C whose respective replenishment possibility times T2 and T3 are later than the earliest time of the management period TW2 are recognized as target devices of interest. Between the replenishment possibility time T2 and the replenishment possibility time T3 corresponding to the AFs 241B and 241C treated as the target devices of interest, the replenishment timing specifying unit 348 specifies the replenishment possibility time T3 that occurs at the latest time as a replenishment possibility time of interest. In addition, the replenishment timing specifying unit 348 specifies any time between the replenishment possibility time T3 specified as the replenishment possibility time of interest and the specified time TT within the management period TW2 as the replenishment timing TH. With this arrangement, the worker is able to perform the work of replenishing the AFs 241A, 241B, 241C, and 241D treated as the component replenishment target devices with reels at any replenishment timing TH between the replenishment possibility time T3 as the replenishment possibility time of interest and the specified time TT.

### Second Embodiment

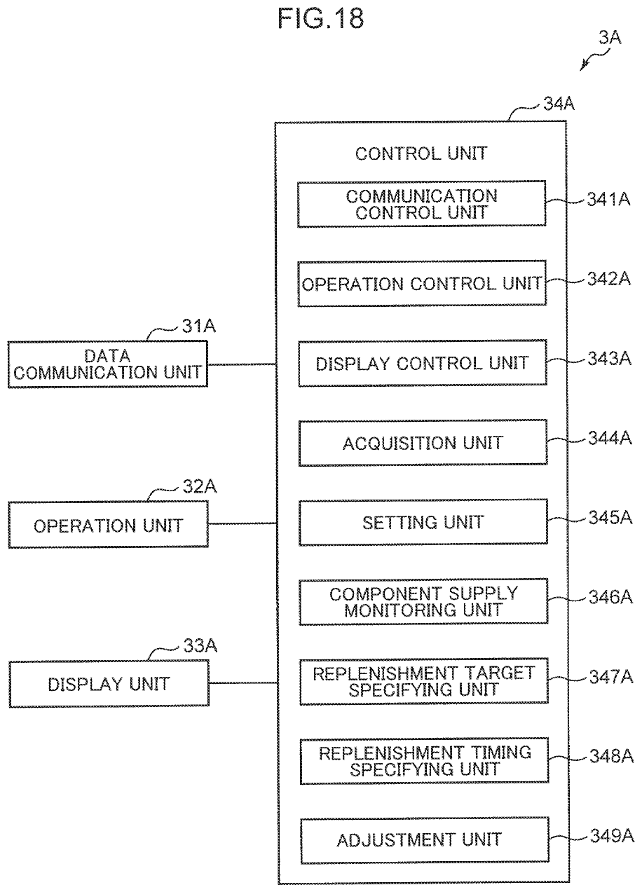

FIG. 18 is a block diagram illustrating a configuration of the component replenishment management system 3A according to a second embodiment. Hereinafter, the component replenishment management system 3A according to the second embodiment will be referred to as the “second component replenishment management system 3A”. In the second component replenishment management system 3A, similarly to the first component replenishment management system 3 described above, a mounter operation management device 4, a production plan management device 5, and a setup management device 6 are communicably connected to each other. In addition, the second component replenishment management system 3A includes a microcontroller for example, and as illustrated in FIG. 18, is provided with a data communication unit 31A, an operation unit 32A, a display unit 33A, and a control unit 34A.

The data communication unit 31A, the operation unit 32A, and the display unit 33A of the second component replenishment management system 3A are configured similarly to the data communication unit 31, the operation unit 32, and the display unit 33 of the first component replenishment management system 3 described earlier, and therefore a description is omitted.

The control unit 34A of the second component replenishment management system 3A is provided with components such as a central processing unit (CPU), read-only memory (ROM) that stores a control program, and random access memory (RAM) used as a work area by the CPU. The control unit 34A controls the data communication unit 31A, the operation unit 32A, and the display unit 33A by having the CPU execute the control program stored in the ROM, and also generates various specification result information related to the replenishment of the reels for each of the plurality of AFs 241 provided in the component supply units 24. As illustrated in FIG. 18, the control unit 34A includes a communication control unit 341A, an operation control unit 342A, a display control unit 343A, an acquisition unit 344A, a setting unit 345A, a component supply monitoring unit 346A, a replenishment target specifying unit 347A, a replenishment timing specifying unit 348A, and an adjustment unit 349A.

The communication control unit 341A controls data communication with the mounter operation management device 4, the production plan management device 5, and the setup management device 6 by the data communication unit 31A. The operation control unit 342A controls the operation unit 32A. The display control unit 343A controls information display operations by the display unit 33A.

(Control Operations Related to Component Replenishment in Second Component Replenishment Management System)

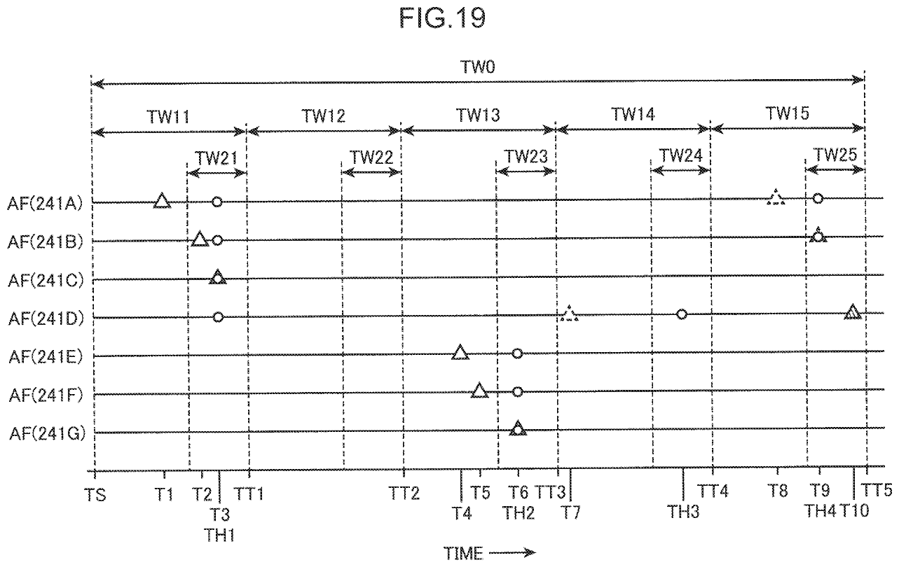

The configuration of the control unit 34A will be described with reference to FIG. 19 in addition to FIG. 18. FIG. 19 is a chart for explaining control operations by the second component replenishment management system 3A. FIG. 19 illustrates an example of supplying components from the seven AFs 241A, 241B, 241C, 241D, 241E, 241F, and 241G among the plurality of AFs 241 disposed in parallel on the wheeled platform 242 of each component supply unit 24, and producing the mounted substrate. Note that it is assumed that tape feeders other than the AFs 241, namely splicing feeders, are also disposed in parallel in the component supply units 24. Additionally, the AFs 241A, 241B, 241C, 241D, 241E, 241F, and 241G may be disposed in the component supply units 24 of the same mounter 2 or in the component supply units 24 of a plurality of different mounters 2.

The acquisition unit 344A acquires a management start time TS that expresses a start time of managing reel replenishment for each of the plurality of AFs 241A, 241B, 241C, 241D, 241E, 241F, and 241G.

The setting unit 345A sets a target period TW0 of new reel replenishment management for each of the plurality of AFs 241A, 241B, 241C, 241D, 241E, 241F, and 241G after the management start time TS. For example, the target period TW0 is a period based on a length of time such as the total production time taken to produce a single substrate type in the production of mounted substrates by the mounters 2 or the total production time taken to produce a single production lot for a single substrate type, and is input by a worker through the operation unit 32A. Furthermore, the setting unit 345A divides the target period TW0 into a plurality of specified periods TW11, TW12, TW13, TW14, and TW15, treating a predetermined specified length of time as a time interval. The specified length of time that prescribes the time interval of each of the specified periods TW11, TW12, TW13, TW14, and TW15 is input by a worker through the operation unit 32A, and is set to any length of time, such as 60 minutes for example. In the following, the specified periods will be referred to as the first specified period TW11, the second specified period TW12, the third specified period TW13, the fourth specified period TW14, and the fifth specified period TW15 in time-series order from earliest to latest. In the present embodiment, the setting unit 345A sets a fixed time interval for each of the first to fifth specified periods TW11, TW12, TW13, TW14, and TW15.

Additionally, the setting unit 345A sets predetermined management periods TW21, TW22, TW23, TW24, and TW25 for the first to fifth specified periods TW11, TW12, TW13, TW14, and TW15, respectively. Each of the management periods TW21, TW22, TW23, TW24, and TW25 is a period whose latest time is the latest specified time TT1, TT2, TT3, TT4, and TT5 in the first to fifth specified periods TW11, TW12, TW13, TW14, and TW15, respectively. The time interval of each of the management periods TW21, TW22, TW23, TW24, and TW25 is input by a worker through the operation unit 32A. In the following the management period TW21 corresponding to the first specified period TW11 will be referred to as the “first management period TW21”, and the specified time TT1 will be referred to as the “first specified time TT1”. Similarly, the management periods will be referred to as the second to fifth management periods TW22, TW23, TW24, and TW25 while the specified times will be referred to as the second to fifth specified times TT2, TT3, TT4, and TT5 in correspondence with the second to fifth specified periods TW12, TW13, TW14, and TW15.

The component supply monitoring unit 346A monitors the supply status of the components E in each of the plurality of AFs 241A, 241B, 241C, 241D, 241E, 241F, and 241G. The component supply monitoring unit 346A specifies, for each of the plurality of AFs 241A, 241B, 241C, 241D, 241E, 241F, and 241G, a replenishment possibility time at which the corresponding AF 241 can be replenished with a new reel, and the remaining count warning time. The component supply monitoring unit 346A specifies the replenishment possibility time and the remaining count warning time on the basis of information supplied to the control unit 34A from the data communication unit 31A, namely the component remaining count information JH24 from the mounter operation management device 4 (or the setup management device 6), the production plan information JH1 from the production plan management device 5, and the setup information JH2 from the setup management device 6. The specific method by which the component supply monitoring unit 346A specifies the replenishment possibility time and the remaining count warning time using the component remaining count information JH24 and the like is similar to that of the component supply monitoring unit 346 described earlier.

Note that in the case where a new reel replenishment timing is specified for each of the plurality of AFs 241A, 241B, 241C, 241D, 241E, 241F, and 241G by the replenishment timing specifying unit 348A described later, the component supply monitoring unit 346A specifies the replenishment possibility time and the remaining count warning time as follows. Namely, in the case where a replenishment timing is specified within one specified period, the component supply monitoring unit 346A assumes that new reel replenishment has been performed at the replenishment timing, and specifies the replenishment possibility time and the remaining count warning time for another specified period later in the time-series order than the one specified period. More specifically, when specifying the replenishment possibility time and the remaining count warning time using the total number of remaining components expressed by the component remaining count information JH24, the component supply monitoring unit 346A updates the total number of remaining components according to the replenishment timing. For example, in the case where the replenishment timing is specified within the first specified period TW11, the component supply monitoring unit 346A assumes that replenishment with a new reel has been performed at the replenishment timing. Thereafter, the component supply monitoring unit 346A updates the total number of remaining components by adding the number components stored in the component storage tape 243 wound around the new reel (initial set number) to the total number of remaining components. The component supply monitoring unit 346A uses the updated total number of remaining components to specify the replenishment possibility time and the remaining count warning time for the second to fifth specified periods TW12, TW13, TW14, and TW15 later than the first specified period TW11 in time-series order.

With regard to the example illustrated in FIG. 19, the replenishment possibility time and the remaining count warning time specified by the component supply monitoring unit 346A in association with each of the plurality of AFs 241A, 241B, 241C, 241D, 241E, 241F, and 241G are described as follows.

A replenishment possibility time T1 is specified for the AF 241A. The replenishment possibility time T1 of the AF 241A is included within the first specified period TW11, and is a time that is earlier than the first specified time TT1 and also earlier than the earliest time of the first management period TW21. Also, a second replenishment possibility time T8 is specified for the AF 241A, under the assumption that replenishment with a new reel will be performed at the first replenishment timing TH1 within the first specified period TW11 specified by the replenishment timing specifying unit 348A described later. The second replenishment possibility time T8 of the AF 241A is included within the fifth specified period TW15, and is a time that is earlier than the fifth specified time TT5 and also earlier than the earliest time of the fifth management period TW25. The remaining count warning time of the AF 241A is not indicated in FIG. 19, but is included in a time window after the fifth specified time TT5.

A replenishment possibility time T2 is specified for the AF 241B. The replenishment possibility time T2 of the AF 241B is included within the first management period TW21 of the first specified period TW11, and is a time that is earlier than the first specified time TT1 and later than the earliest time of the first management period TW21. Also, a second replenishment possibility time T9 is specified for the AF 241B, under the assumption that replenishment with a new reel will be performed at the first replenishment timing TH1 within the first specified period TW11 specified by the replenishment timing specifying unit 348A described later. The second replenishment possibility time T9 of the AF 241B is included within the fifth management period TW25 of the fifth specified period TW15, and is a time that is earlier than the fifth specified time TT5 and later than the earliest time of the fifth management period TW25. The remaining count warning time of the AF 241B is not indicated in FIG. 19, but is included in a time window after the fifth specified time TT5.

A replenishment possibility time T3 is specified for the AF 241C. The replenishment possibility time T3 of the AF 241C is included within the first management period TW21 of the first specified period TW11, and is a time earlier than the first specified time TT1 and also later than the earliest time of the first management period TW21. The replenishment possibility time T3 of the AF 241C is a time later than the replenishment possibility time T2 of the AF 241B. The remaining count warning time of the AF 241C is not indicated in FIG. 19, but is included in a time window after the fifth specified time TT5.

The replenishment possibility time of the AF 241D is not illustrated in FIG. 19. The replenishment possibility time of the AF 241D is a time earlier than the first specified time TT1 of the first specified period TW11 and also earlier than the management start time TS, and is included in a time window before the management start time TS. Also, a second replenishment possibility time T7 is specified for the AF 241D, under the assumption that replenishment with a new reel will be performed at the first replenishment timing TH1 within the first specified period TW11 specified by the replenishment timing specifying unit 348A described later. The second replenishment possibility time T7 of the AF 241D is included within the fourth specified period TW14, and is a time that is earlier than the fourth specified time TT4 and also earlier than the earliest time of the fourth management period TW24. Furthermore, a remaining count warning time T10 is specified for the AF 241D. The remaining count warning time T10 of the AF 241D is included within the fifth specified period TW25 of the fifth specified period TW15, and is a time that is earlier than the fifth specified time TT5 and also later than the earliest time of the fifth specified period TW25.

A replenishment possibility time T4 is specified for the AF 241E. The replenishment possibility time T4 of the AF 241E is included within the third specified period TW13, and is a time earlier than the third specified time TT3 and also earlier than the earliest time of the third management period TW23. The remaining count warning time of the AF 241E is not indicated in FIG. 19, but is included in a time window after the fifth specified time TT5.

A replenishment possibility time T5 is specified for the AF 241F. The replenishment possibility time T5 of the AF 241F is included within the third specified period TW13, and is a time earlier than the third specified time TT3 and also earlier than the earliest time of the third management period TW23. The remaining count warning time of the AF 241F is not indicated in FIG. 19, but is included in a time window after the fifth specified time TT5.

A replenishment possibility time T6 is specified for the AF 241G. The replenishment possibility time T6 of the AF 241G is included within the third management period TW23 of the third specified period TW13, and is a time earlier than the third specified time TT3 and also later than the earliest time of the third management period TW23. The remaining count warning time of the AF 241G is not indicated in FIG. 19, but is included in a time window after the fifth specified time TT5.

Next, the replenishment target specifying unit 347A specifies component replenishment target devices targeted for replenishment with a new reel for each of the first to fifth management periods TW21, TW22, TW23, TW24, and TW25 in the first to fifth specified periods TW11, TW12, TW13, TW14, and TW15. The replenishment target specifying unit 347A specifies all of the AFs 241 whose replenishment possibility time is a time earlier than the first to fifth specified times TT1, TT2, TT3, TT4, and TT5 in each of the first to fifth specified periods TW11, TW12, TW13, TW14, and TW15 as the component replenishment target devices.

In the example illustrated in FIG. 19, in the first specified period TW11, the replenishment target specifying unit 347A specifies all of the AFs 241A, 241B, 241C, and 241D whose replenishment possibility time is a time earlier than the first specified time TT1 as the component replenishment target devices targeted for replenishment with a new reel within the first management period TW21. In the second specified period TW12, because an AF 241 whose replenishment possibility time is a time earlier than the second specified time TT2 does not exist, the replenishment target specifying unit 347A determines that no component replenishment target device targeted for replenishment with a new reel exists within the second management period TW22.

In the third specified period TW13, the replenishment target specifying unit 347A specifies all of the AFs 241E, 241F, and 241G whose replenishment possibility time is a time earlier than the third specified time TT3 as the component replenishment target devices targeted for replenishment with a new reel within the third management period TW23. In the fourth specified period TW14, the replenishment target specifying unit 347A specifies the AF 241D whose replenishment possibility time is a time earlier than the fourth specified time TT4 as the component replenishment target device targeted for replenishment with a new reel within the fourth management period TW24. In the fifth specified period TW15, the replenishment target specifying unit 347A specifies the AFs 241A and 241B whose replenishment possibility time is a time earlier than the fifth specified time TT5 as the component replenishment target devices targeted for replenishment with a new reel within the fifth management period TW25.

In the second component replenishment management system 3A, the replenishment target specifying unit 347A specifies component replenishment target devices targeted for replenishment with a new reel for each of the first to fifth management periods TW21, TW22, TW23, TW24, and TW25 in the plurality of first to fifth specified periods TW11, TW12, TW13, TW14, and TW15 divided by treating a predetermined specified length of time as the time interval. With this arrangement, “batch replenishment” becomes possible in which the reel replenishment work is performed all at once by a worker for the AFs 241 that can be replenished with a new reel in each of the first to fifth management periods TW21, TW22, TW23, TW24, and TW25 in the plurality of first to fifth specified periods TW11, TW12, TW13, TW14, and TW15. For this reason, the burden imposed on the worker by the replenishment work can be reduced. In addition, because the time interval of each of the plurality of first to fifth specified periods TW11, TW12, TW13, TW14, and TW15 is set to a fixed interval by the setting unit 345A, the worker is able to perform the work of replenishing component replenishment target devices with reels periodically on a fixed time interval.

Next, the replenishment timing specifying unit 348A specifies the same new reel replenishment timing for the AFs 241 specified as the component replenishment target devices by the replenishment target specifying unit 347A in each of the first to fifth management periods TW21, TW22, TW23, TW24, and TW25 in the first to fifth specified periods TW11, TW12, TW13, TW14, and TW15. The method of specifying the replenishment timing for each of the first to fifth management periods TW21, TW22, TW23, TW24, and TW25 by the replenishment timing specifying unit 348A is similar to that of the replenishment timing specifying unit 348 described earlier.

In the example illustrated in FIG. 19, the replenishment timing specifying unit 348A specifies any time within each of the first to fifth specified periods TW11, TW12, TW13, TW14, and TW15 in the first to fifth management periods TW21, TW22, TW23, TW24, and TW25 as the replenishment timing. The replenishment timing specifying unit 348A specifies the first replenishment timing TH1 for the AFs 241A, 241B, 241C, and 241D treated as the component replenishment target devices as the replenishment timing within the first management period TW21 of the first specified period TW11. Also, the replenishment timing specifying unit 348A does not specify a replenishment timing in the second management period TW22 according to the result of the determination by the replenishment target specifying unit 347A indicating that a component replenishment target device corresponding to the second specified period TW12 does not exist. Also, the replenishment timing specifying unit 348A specifies the second replenishment timing TH2 for the AFs 241E, 241F, and 241G treated as the component replenishment target devices as the replenishment timing within the third management period TW23 of the third specified period TW13. Also, the replenishment timing specifying unit 348A specifies the third replenishment timing TH3 for the AF 241D treated as the component replenishment target device as the replenishment timing within the fourth management period TW24 of the fourth specified period TW14. Also, the replenishment timing specifying unit 348A specifies the fourth replenishment timing TH4 for the AFs 241A and 241B treated as the component replenishment target devices as the replenishment timing within the fifth management period TW25 of the fifth specified period TW15.

(Modification of Control Operations by Second Component Replenishment Management System)

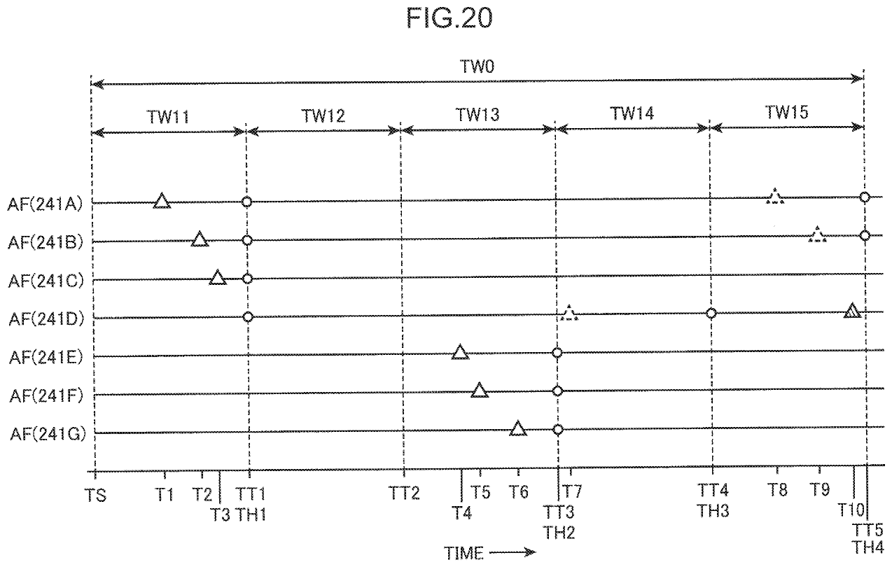

FIG. 20 is a diagram for explaining a first modification of control operations by the second component replenishment management system 3A. The replenishment timing specifying unit 348A of the second component replenishment management system 3A may also be configured to specify the first to fifth specified times TT1, TT2, TT3, TT4, and TT5 within the first to fifth specified periods TW11, TW12, TW13, TW14, and TW15 as the replenishment timings. Note that in the case where the replenishment timing specifying unit 348A performs an operation of specifying the specified times TT1, TT2, TT3, TT4, and TT5 as the replenishment timings, the setting unit 345A does not have to set the management periods TW21, TW22, TW23, TW24, and TW25 described earlier, and may simply set the first to fifth specified periods TW11, TW12, TW13, TW14, and TW15 only. Also, the setting unit 345A may set the management periods TW21, TW22, TW23, TW24, and TW25 described earlier, and in the case where the replenishment timing specifying unit 348A performs an operation of specifying the specified times TT1, TT2, TT3, TT4, and TT5 as the replenishment timings, the setting unit 345A may be configured to set the time interval of the management periods TW21, TW22, TW23, TW24, and TW25 to “0 (zero)”. A worker is able to perform the work of replenishing the component replenishment target devices with reels by treating the first to fifth specified times TT1, TT2, TT3, TT4, and TT5 that serve as the basis of the first to fifth specified periods TW11, TW12, TW13, TW14, and TW15 as the replenishment timings.

In the example illustrated in FIG. 20, the replenishment timing specifying unit 348A sets the first specified time TT1 as the first replenishment timing TH1 for the AFs 241A, 241B, 241C, and 241D treated as the component replenishment target devices within the first specified period TW11. Also, the replenishment timing specifying unit 348A does not specify a replenishment timing in the second specified period TW12 according to the result of the determination by the replenishment target specifying unit 347A indicating that a component replenishment target device corresponding to the second specified period TW12 does not exist. Also, the replenishment timing specifying unit 348A sets the third specified time TT3 as the second replenishment timing TH2 for the AFs 241E, 241F, and 241G treated as the component replenishment target devices within the third specified period TW13. Also, the replenishment timing specifying unit 348A sets the fourth specified time TT4 as the third replenishment timing TH3 for the AFs 241D treated as the component replenishment target devices within the fourth specified period TW14. Also, the replenishment timing specifying unit 348A sets the fifth specified time TT5 as the fourth replenishment timing TH4 for the AFs 241A and 241B treated as the component replenishment target devices within the fifth specified period TW15.

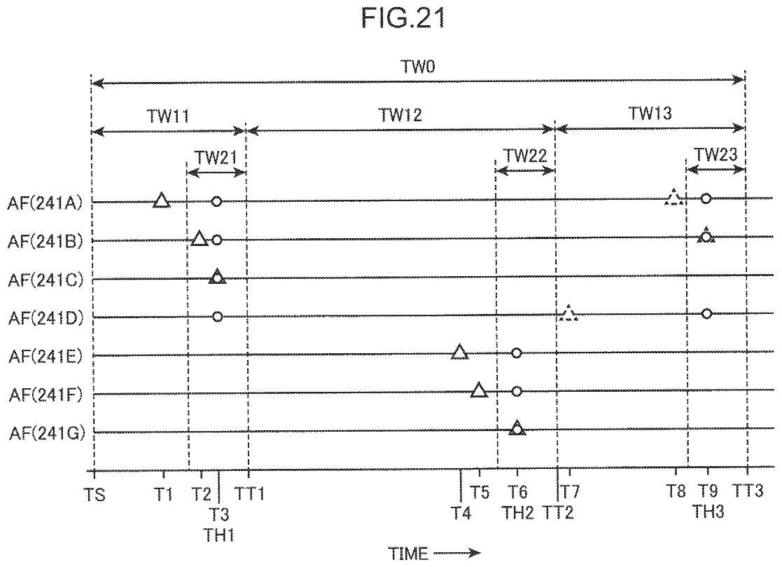

FIG. 21 is a diagram for explaining a second modification of control operations by the second component replenishment management system 3A. The operation unit 32A of the second component replenishment management system 3A may be configured to receive an operation of inputting command information related to setting a time interval of each specified period to use when the setting unit 345A divides the target period TW0 into a plurality of specified periods. In this case, the time interval of each specified period may be the same or different.

The setting unit 345A sets a target period TW0 of new reel replenishment management for each of the plurality of AFs 241A, 241B, 241C, 241D, 241E, 241F, and 241G after the management start time TS. Furthermore, the setting unit 345A sets a time interval for each of the plurality of specified periods based on command information related to the setting of a time interval of each specified period input through the operation unit 32A. In the example illustrated in FIG. 21, different time intervals are respectively set for the first to third specified periods TW11, TW12, and TW13. Also, the setting unit 345A divides the target period TW0 into the plurality of first to third specified periods TW11, TW12, and TW13 according to the set time intervals. Additionally, the setting unit 345A sets the first to third management periods TW21, TW22, and TW23 for each of the first to third specified periods TW11, TW12, and TW13.

When the first to third management periods TW21, TW22, and TW23 are set by the setting unit 345A, the component supply monitoring unit 346A specifies the replenishment possibility time at which replenishment is possible and the remaining count warning time for each of the plurality of AFs 241A, 241B, 241C, 241D, 241E, 241F, and 241G. Next, the replenishment target specifying unit 347A specifies the component replenishment target devices targeted for replenishment with a new reel for each of the first to third management periods TW21, TW22, and TW23. Additionally, the replenishment timing specifying unit 348A specifies the same new reel replenishment timing for the AFs 241 specified as the component replenishment target devices by the replenishment target specifying unit 347A in each of the first to third management periods TW21, TW22, and TW23.

As above, a worker is able to designate a time interval for each of the plurality of first to third specified periods TW11, TW12, and TW13 through the operation unit 32A.

Note that in the example illustrated in FIGS. 19 to 21 described above, the setting unit 345A performs the operation of dividing the entire target period TW0 into a plurality of specified periods at the management start time TS, but the setting unit 345A may also be configured to perform an operation of successively setting the specified periods automatically during the target period TW0. For example, every time a specified time set to the latest time of a specified period is reached, the setting unit 345A may successively set the next specified period.

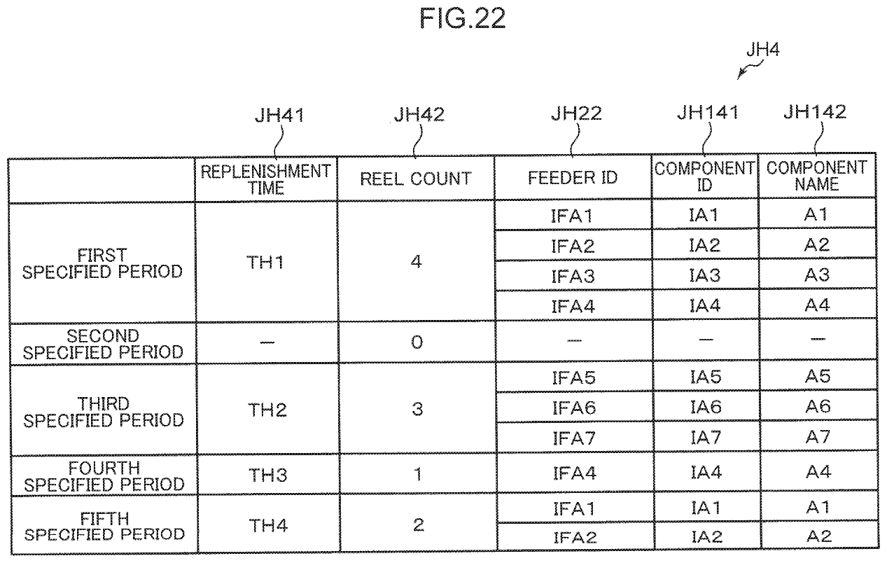

In the second component replenishment management system 3A, the replenishment target specifying unit 347A generates replenishment specification result information expressing the specification result of the component replenishment target device(s) in each of the plurality of specified periods. Note that information related to the replenishment timing specified by the replenishment timing specifying unit 348A may also be added to the replenishment specification result information generated by the replenishment target specifying unit 347A. FIG. 22 is a diagram for explaining replenishment specification result information JH4 generated by the replenishment target specifying unit 347A of the second component replenishment management system 3A.

The replenishment specification result information JH4 is information including replenishment timing information JH41, replenishment count information JH42, the feeder identification information JH22, the component identification information JH141, and the component type specification information JH142. The replenishment timing information JH41 is information expressing the replenishment timing of each of the first to fifth specified periods TW11, TW12, TW13, TW14, and TW15 specified by the replenishment timing specifying unit 348A. The replenishment count information JH42 is information expressing, for each of the first to fifth specified periods TW11, TW12, TW13, TW14, and TW15, the total number of new reels to be used to replenish the AFs 241 treated as the component replenishment target devices specified by the replenishment target specifying unit 347A.

The feeder identification information JH22, the component identification information JH141, and the component type specification information JH142 express information related to the new reels to be used to replenish the AFs 241 treated as the component replenishment target devices specified by the replenishment target specifying unit 347A for each of the first to fifth specified periods TW11, TW12, TW13, TW14, and TW15.

The replenishment specification result information JH4 is displayed on the display unit 33A controlled by the display control unit 343A. The replenishment specification result information JH4 is also supplied to the data communication unit 31A and transmitted to the mounter operation management device 4 from the data communication unit 31A controlled by the communication control unit 341A. Based on the replenishment specification result information JH4 input into the mounter operation management device 4, a worker on the production line is able to perform the work of replenishing the AFs 241 with reels. Note that the replenishment specification result information JH4 in the example illustrated in FIG. 22 that is displayed on the display unit 33A and the like is specification result information for the case in which the setting unit 345A divides the entire target period TW0 into a plurality of specified periods at the management start time TS, and the operations described earlier by each of the component supply monitoring unit 346A, the replenishment target specifying unit 347A, and the replenishment timing specifying unit 348A are executed accordingly. After the replenishment specification result information JH4 is displayed on the display unit 33A and the like, in the case where the setting unit 345A successively sets the next specified period during the target period TW0 every time a specified time set to the latest time of a specified period is reached for example, and the operations described earlier by each of the component supply monitoring unit 346A, the replenishment target specifying unit 347A, and the replenishment timing specifying unit 348A are executed accordingly, specification result information for each operation may also be successively displayed on the display unit 33A and the like. Also, in some cases, after the replenishment specification result information JH4 is displayed on the display unit 33A and the like, factors such as the component supply status of a component supply device monitored by the component supply monitoring unit 346A may change, and a change in the specification result by the replenishment target specifying unit 347A and the replenishment timing specifying unit 348A may occur accordingly. In such cases, at a timing during the target period TW0, such as at a specified time set to the latest time of a specified period for example, the operations described earlier by each of the component supply monitoring unit 346A, the replenishment target specifying unit 347A, and the replenishment timing specifying unit 348A may be executed, and the replenishment specification result information updated according to the execution of the operations may be displayed on the display unit 33A and the like.

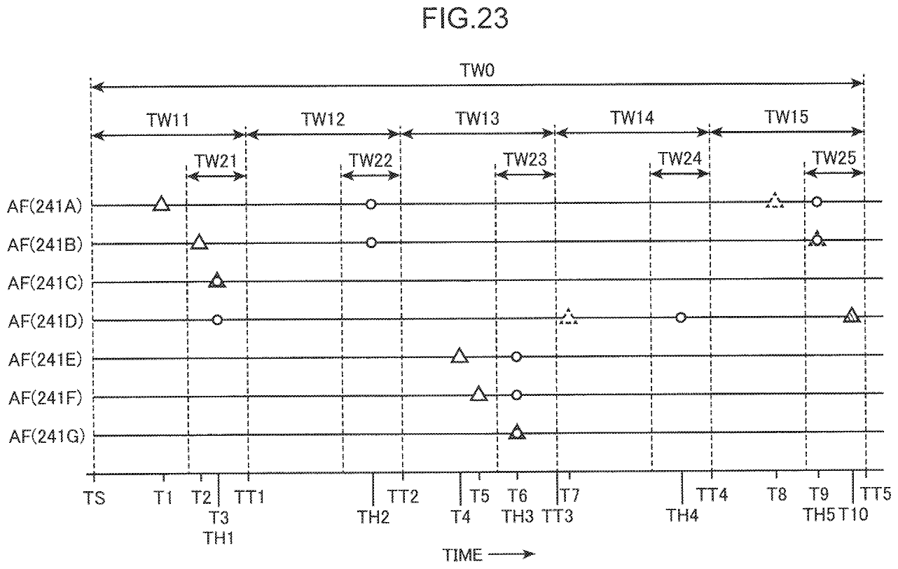

In addition, as illustrated in FIG. 18, the second component replenishment management system 3A according to the present embodiment may also be provided with the adjustment unit 349A. The adjustment unit 349A performs a replenishment count adjustment process that adjusts the number of component replenishment target devices in each of the plurality of specified periods, the component replenishment target devices being specified by the replenishment target specifying unit 347A. Operations by the adjustment unit 349A will be described with reference to FIG. 23. FIG. 23 is a chart for explaining operations by the adjustment unit 349A of the second component replenishment management system 3A.

The replenishment count adjustment process of the adjustment unit 349A will be described under the assumption that, prior to the replenishment count adjustment process by the adjustment unit 349A, the replenishment target specifying unit 347A has specified the component replenishment target devices for each of the plurality of specified periods, like in the example illustrated in FIG. 19 described earlier. First, the adjustment unit 349A calculates the number of component replenishment target devices specified by the replenishment target specifying unit 347A for each of the plurality of first to fifth specified periods TW11, TW12, TW13, TW14, and TW15.

In the example illustrated in FIG. 19, the replenishment target specifying unit 347A specifies the four AFs 241A, 241B, 241C, and 241D as the component replenishment target devices within the first management period TW21 of the first specified period TW11. For this reason, the adjustment unit 349A calculates “4” as the number of component replenishment target devices in the first specified period TW11. Also, the replenishment target specifying unit 347A determines that no component replenishment target devices exist within the second management period TW22 of the second specified period TW12. For this reason, the adjustment unit 349A calculates “0 (zero)” as the number of component replenishment target devices in the second specified period TW12. Also, the replenishment target specifying unit 347A specifies the three AFs 241E, 241F, and 241G as the component replenishment target devices within the third management period TW23 of the third specified period TW13. For this reason, the adjustment unit 349A calculates “3” as the number of component replenishment target devices in the third specified period TW13. Also, the replenishment target specifying unit 347A specifies the one AF 241D as the component replenishment target device within the fourth management period TW24 of the fourth specified period TW14. For this reason, the adjustment unit 349A calculates “1” as the number of component replenishment target devices in the fourth specified period TW14. Also, the replenishment target specifying unit 347A specifies the two AFs 241A and 241B as the component replenishment target device within the fifth management period TW25 of the fifth specified period TW15. For this reason, the adjustment unit 349A calculates “2” as the number of component replenishment target devices in the fifth specified period TW15.

Based on the above calculation result, the adjustment unit 349A performs the replenishment count adjustment process that adjusts the number of component replenishment target devices for each of the plurality of first to fifth specified periods TW11, TW12, TW13, TW14, and TW15. In the replenishment count adjustment process, the adjustment unit 349A compares the numbers of component replenishment target devices in specified periods adjacent to each other in the time series. More specifically, the adjustment unit 349A compares the numbers of component replenishment target devices between the first specified period TW11 and the second specified period TW12, between the second specified period TW12 and the third specified period TW13, between the third specified period TW13 and the fourth specified period TW14, and between the fourth specified period TW14 and the fifth specified period TW15 adjacent to each other in the time series.

Additionally, the adjustment unit 349A compares the numbers of component replenishment target devices, and in the case where the number in a first specified period of interest that is earlier in the time-series order is greater than a predetermined reference number, while in addition, the number in a second specified period of interest that is later in the time-series order is less than the reference number, the adjustment unit 349A performs a replenishment count adjustment process of allocating a portion of the component replenishment target devices in the first specified period of interest as component replenishment target devices targeted for replenishment with a new reel in the second specified period of interest. The predetermined reference number is the average of the total numbers of component replenishment target devices for each of the plurality of first to fifth specified periods TW11, TW12, TW13, TW14, and TW15. Furthermore, in the case where the remaining count warning time is included within the third specified period of interest that is adjacent later in the time series than the second specified period of interest in the plurality of the first to fifth specified periods TW11, TW12, TW13, TW14, and TW15, the adjustment unit 349A does not perform the replenishment count adjustment process.

When described specifically with reference to FIGS. 19 and 23, the replenishment count adjustment process by the adjustment unit 349A is as follows.

The adjustment unit 349A compares the numbers of component replenishment target devices between the first specified period TW11 and the second specified period TW12 adjacent to each other in the time series. The component replenishment target devices in the first specified period TW11 (first specified period of interest) that is earlier in the time-series order are AF241A, 241B, 241C, and 241D, where the number is “4” more than a predetermined reference number (for example, the average value=2). On the other hand, there is no component replenishment target device in the second specified period TW12 (second specified period of interest) that is later in the time-series order, where the number is “0” less than the predetermined reference number (for example, the average=2) (see FIG. 19). In this case, the adjustment unit 349A allocates a portion (the two AFs 241A and 241B) of the component replenishment target devices in the first specified period TW11 (first specified period of interest) as the component replenishment target devices targeted for replenishment with a new reel in the second specified period TW12 (second specified period of interest) (see FIG. 23). With this arrangement, the burden of the reel replenishment work with respect to the component replenishment target devices specified by the replenishment target specifying unit 347A can be leveled out among the plurality of first to fifth specified periods TW11, TW12, TW13, TW14, and TW15.

Further, the adjustment unit 349A compares the numbers of component replenishment target devices between the second specified period TW12 and the third specified period TW13 adjacent to each other in the time series. The component replenishment target device in the second specified period TW12 (first specified period of interest) that is earlier in the time-series order does not exist, where the number is “0” less than a predetermined reference number (for example, the average value=2). On the other hand, the component replenishment target devices in the third specified period TW13 (second specified period of interest) that is later in the time-series order are AF241E, 241F, and 241G, where the number is “3” more than the predetermined reference number (for example, the average=2) (see FIG. 19). In this case, the adjustment unit 349A does not perform the replenishment count adjustment process.

Further, the adjustment unit 349A compares the numbers of component replenishment target devices between the third specified period TW13 and the fourth specified period TW14 adjacent to each other in the time series. The component replenishment target devices in the third specified period TW13 (first specified period of interest) that is earlier in the time-series order are AF241E, 241F, and 241G, where the number is “3” more than a predetermined reference number (for example, the average value=2). On the other hand, the component replenishment target device in the fourth specified period TW14 (second specified period of interest) that is later in the time-series order is AF241D, where the number is “1” less than the predetermined reference number (for example, the average=2). However, the remaining count warning time T10 is included within the fifth specified period TW15 (third specified period of interest) that is adjacent later in the time series than the fourth specified period TW14 (second specified period of interest). In this case, the adjustment unit 349A does not perform the replenishment count adjustment process.

In the replenishment work with respect to the component replenishment target device in the fourth specified period TW14 (second specified period of interest), the replenishment work with respect to the AF 241D whose remaining count warning time T10 is included within the fifth specified period TW15 (third specified period of interest) that is adjacent later in the time series than the fourth specified period TW14 becomes urgent work, and careful work is demanded. In this way, in the case where the remaining count warning time T10 is included within the fifth specified period TW15 (third specified period of interest), and the replenishment work in the fourth specified period TW14 (second specified period of interest) is expected to be urgent work, the adjustment unit 349A does not perform the replenishment count adjustment process. With this arrangement, a portion of the component replenishment target devices in the third specified period TW13 (first specified period of interest) is not allocated to the fourth specified period TW14 (second specified period of interest). For this reason, a worker is able to concentrate on the urgent replenishment work in the fourth specified period TW14 (second specified period of interest).

Further, the adjustment unit 349A compares the numbers of component replenishment target devices between the fourth specified period TW14 and the fifth specified period TW15 adjacent to each other in the time series. The component replenishment target device in the fourth specified period TW14 (first specified period of interest) that is earlier in the time-series order is AF241D, where the number is “1” less than a predetermined reference number (for example, the average value=2). On the other hand, the component replenishment target devices in the fifth specified period TW15 (second specified period of interest) that is later in the time-series order are AF241A and 241B, where the number is “2” same as the predetermined reference number (for example, the average=2). In this case, the adjustment unit 349A does not perform the replenishment count adjustment process.

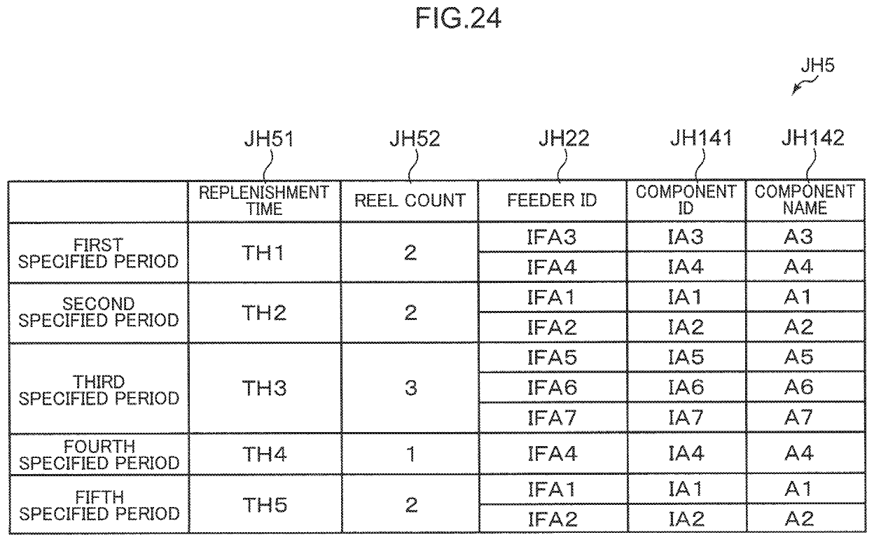

In the second component replenishment management system 3A, the adjustment unit 349A generates adjustment result information expressing the adjustment result of the number of the component replenishment target device(s) in each of the plurality of specified periods. FIG. 24 is a table for explaining adjustment result information JH5 generated by the adjustment unit 349A.

The adjustment result information JH5 is information including replenishment timing information JH51, replenishment count information JH52, the feeder identification information JH22, the component identification information JH141, and the component type specification information JH142. The replenishment timing information JH51 is information expressing the replenishment timing of each of the first to fifth specified periods TW11, TW12, TW13, TW14, and TW15 specified by the replenishment timing specifying unit 348A after the replenishment count adjustment process by the adjustment unit 349A. The replenishment count information JH52 is information expressing, for each of the first to fifth specified periods TW11, TW12, TW13, TW14, and TW15, the total number of new reels to be used to replenish the AFs 241 after the replenishment count adjustment process by the adjustment unit 349A.

The feeder identification information JH22, the component identification information JH141, and the component type specification information JH142 express information related to the new reels to be used to replenish the AFs 241 after the replenishment count adjustment process by the adjustment unit 349A for each of the first to fifth specified periods TW11, TW12, TW13, TW14, and TW15.

The adjustment result information JH5 is displayed on the display unit 33A controlled by the display control unit 343A. The adjustment result information JH5 is also supplied to the data communication unit 31A and transmitted to the mounter operation management device 4 from the data communication unit 31A controlled by the communication control unit 341A. Based on the adjustment result information JH5 input into the mounter operation management device 4, a worker on the production line is able to perform the work of replenishing the AFs 241 with reels.

The above describes a component replenishment management system and a component mounting system according to an embodiment of the present disclosure, but the present disclosure is not limited thereto, and may adopt a modified embodiment like the following, for example.

In the above embodiment, the component supply devices attached to the mounters 2 are described as being AFs 241 containing tape feeders into which reels 2420 around which component storage tape 243 is wound can be loaded, but the present disclosure is not limited to such a configuration. It is sufficient for the component supply devices to be devices into which a plurality of component storage members storing components can be loaded, and for example, the component supply devices may be tray feeders into which a plurality of pallets containing trays on which components are placed can be loaded, or stick feeders into which a plurality of sticks storing components can be loaded.

### First Modified Embodiment

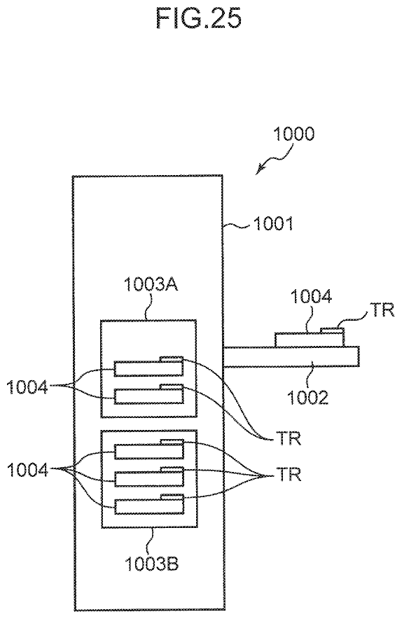

FIG. 25 is a diagram illustrating a tray feeder 1000 as the component supply device of a first modification. The tray feeder 1000 is installed in a component supply unit 24 of a mounter 2. A plurality of tray feeders 1000 can be disposed in parallel in the component supply unit 24. The tray feeder 1000 is configured such that components can be supplied while being held on a pallet 1004. On the pallet 1004, at least one tray TR holding a plurality of components is placed. The tray TR is rectangular in plan view, and on the top face thereof, a plurality of component compartments are provided in a matrix. The component compartments respectively store components at regular intervals. A plurality of pallets 1004 configured in this way are housed in each of a first magazine 1003A and a second magazine 1003B.

The first magazine 1003A and the second magazine 1003B function as component storage members that house the plurality of pallets 1004 on which the trays TR holding components are placed. The first magazine 1003A and the second magazine 1003B are each independently movable in the vertical direction inside a cover body 1001. When producing a mounted substrate, the pallets 1004 housed in the first magazine 1003A and the second magazine 1003B are moved to a table 1002 provided projecting outward from the cover body 1001, thereby supplying the components held in the pallets 1004.

During the production of the mounted substrate, even if the components held in the pallets 1004 housed in the first magazine 1003A run out, the pallets 1004 housed in the second magazine 1003B are moved to the table 1002, thereby supplying the components held in the pallets 1004. At this time, during the production of the mounted substrate, a worker is able to remove the first magazine 1003A that has run out of components from the cover body 1001, and replenish the tray feeder 1000 with a new magazine. Here, the replenishment of the tray feeder 1000 with a new magazine is managed by the first component replenishment management system 3 or the second component replenishment management system 3A. Hereinafter, the replenishment management by the first component replenishment management system 3 will be described.

In the first component replenishment management system 3, the replenishment target specifying unit 347 specifies all of the tray feeders 1000 that can be replenished with a new magazine within a management period based on a specified time set by the setting unit 345 as component replenishment target devices. With this arrangement, “batch replenishment” becomes possible in which the magazine replenishment work is performed all at once by a worker for the tray feeders 1000 that can be replenished with a new magazine within the management period. For this reason, the worker is able to perform the “batch replenishment” of new magazines by treating the specified time that serves as the basis of the management period as an estimate of the work start time for the replenishment work. Consequently, the burden imposed on the worker by the replenishment work can be reduced.

Further, the replenishment timing specifying unit 348 specifies the replenishment timing of the same new magazine in the management period for the tray feeder 1000 specified as component replenishment target devices by the replenishment target specifying unit 347. With this arrangement, the worker is able to perform the work of replenishing the tray feeder 1000 specified as the component replenishment target devices with a new magazine at the same replenishment timing.

### Second Modified Embodiment

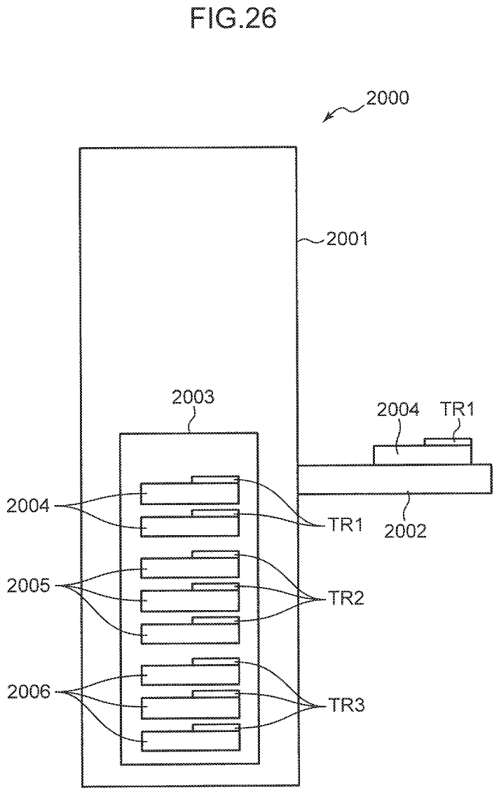

FIG. 26 is a diagram illustrating a tray feeder 2000 as the component supply device of a second modification. The tray feeder 2000 is installed in a component supply unit 24 of a mounter 2. A plurality of tray feeders 2000 can be disposed in parallel in the component supply unit 24. The tray feeder 2000 is configured such that a single magazine 2003 is movable in the vertical direction inside a cover body 2001. The magazine 2003 houses a plurality of first pallets 2004, a plurality of second pallets 2005, and a plurality of third pallets 2006.

On each of the first pallets 2004, at least one first tray TR1 holding a plurality of components is placed. The components held in the first tray TR1 are the same type of component for each first pallet 2004. Similarly, on each of the second pallets 2005, at least one second tray TR2 holding a plurality of components is placed. The components held in the second tray TR2 are the same type of component for each second pallet 2005. However, the components held in the second tray TR2 are a different type of component from the components held in the first tray TR1. Also, on each of the third pallets 2006, at least one third tray TR3 holding a plurality of components is placed. The components held in the third tray TR3 are the same type of component for each third pallet 2006. However, the components held in the third tray TR3 are a different type of component from the components held in each of the first tray TR1 and the second tray TR2.

Each of the first pallets 2004, the second pallets 2005, and the third pallets 2006 functions as a component storage member on which the trays TR1, TR2, and TR3 holding a plurality of components are placed, respectively. When producing a mounted substrate, each of the first pallets 2004, the second pallets 2005, and the third pallets 2006 housed in the magazine 2003 is moved to a table 2002 provided projecting outward from the cover body 2001, thereby supplying the components held in the trays TR1, TR2, and TR3.

During the production of the mounted substrate, even if the components held in the first tray TR1 placed on one of the first pallets 2004 among the plurality of first pallets 2004 runs out, another first pallet 2004 is moved to the table 2002, thereby supplying components held in the first tray TR1. At this time, during the production of the mounted substrate, a worker is able to remove the first pallet 2004 that has run out of components from the cover body 2001, and replenish the tray feeder 2000 with a new first pallet. Similarly, during the production of the mounted substrate, even if the components held in the second tray TR2 placed on one of the second pallets 2005 among the plurality of second pallets 2005 runs out, another second pallet 2005 is moved to the table 2002, thereby supplying components held in the second tray TR2. At this time, during the production of the mounted substrate, a worker is able to remove the second pallet 2005 that has run out of components from the cover body 2001, and replenish the tray feeder 2000 with a new second pallet. Also, during the production of the mounted substrate, even if the components held in the third tray TR3 placed on one of the third pallets 2006 among the plurality of third pallets 2006 runs out, another third pallet 2006 is moved to the table 2002, thereby supplying components held in the third tray TR3. At this time, during the production of the mounted substrate, a worker is able to remove the third pallet 2006 that has run out of components from the cover body 2001, and replenish the tray feeder 2000 with a new third pallet.

Note that in the tray feeder 2000, the number of each of the first pallets 2004, the second pallets 2005, and the third pallets 2006 may be different in some cases. In such cases, the number of new pallets used to replenish the tray feeder 2000 and fill up the same components will be different for each of the first pallets, the second pallets, and the third pallets. Also, the number of replenishing pallets may also change depending on the overall number of remaining components of a component type corresponding to the pallets when replenishing the tray feeder 2000 with new pallets.

Here, the replenishment of the tray feeder 2000 with a new pallet is managed by the first component replenishment management system 3 or the second component replenishment management system 3A. Hereinafter, the replenishment management by the first component replenishment management system 3 will be described.

In the first component replenishment management system 3, the replenishment target specifying unit 347 specifies all of the tray feeders 2000 that can be replenished with a new pallet within a management period based on a specified time set by the setting unit 345 as component replenishment target devices. With this arrangement, “batch replenishment” becomes possible in which the pallet replenishment work is performed all at once by a worker for the tray feeders 2000 that can be replenished with the new pallet within the management period. For this reason, the worker is able to perform the “batch replenishment” of new pallets by treating the specified time that serves as the basis of the management period as an estimate of the work start time for the replenishment work. Consequently, the burden imposed on the worker by the replenishment work can be reduced.

Further, the replenishment timing specifying unit 348 specifies the replenishment timing of the same new pallet in the management period for the tray feeder 2000 specified as component replenishment target devices by the replenishment target specifying unit 347. With this arrangement, the worker is able to perform the work of replenishing the tray feeder 2000 specified as the component replenishment target devices with the new pallet at the same replenishment timing.

### Third Modified Embodiment

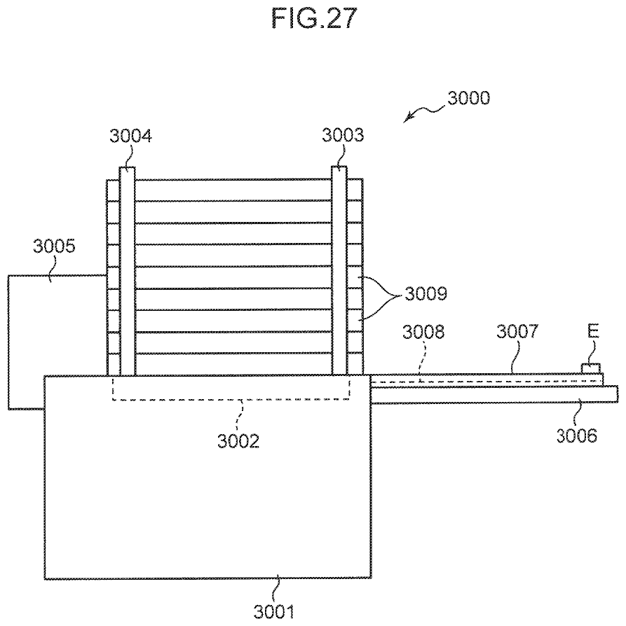

FIG. 27 is a diagram illustrating a stick feeder 3000 as the component supply device of a third modification. The stick feeder 3000 is installed in a component supply unit 24 of a mounter 2. A plurality of stick feeders 3000 can be disposed in parallel in the component supply unit 24. The stick feeder 3000 is configured to supply components E stored in a stick 3009 as a cylindrical component storage member while pushing out the components E from the stick 3009. The stick feeder 3000 is provided with a frame body 3001, a stick table 3002 provided in an upper part of the frame body 3001, a first chuck 3003, a second chuck 3004, a component pushing mechanism 3005, a guide frame 3006, a pair of guide rails 3007, and a conveyor belt 3008.

The frame body 3001 is shaped like an empty box open on the top. The stick table 3002 is disposed inside the upper part of the frame body 3001. A plurality of sticks 3009 can be stacked on top of the stick table 3002. The first chuck 3003 is capable of holding the leading ends of the plurality of sticks 3009 other than the lowest stick 3009 on top of the stick table 3002 at the same time. Similarly, the second chuck 3004 is capable of holding the trailing ends of the plurality of sticks 3009 other than the lowest stick 3009 on top of the stick table 3002 at the same time.

The component pushing mechanism 3005 pushes out the components E from the front of the lowest stick 3009 among the plurality of sticks 3009 on top of the stick table 3002. The guide frame 3006 is affixed to a front part of the frame body 3001, and the pair of guide rails 3007 are supported by the guide frame 3006. Additionally, the conveyor belt 3008 is provided between the pair of guide rails 3007. The components E pushed out to the front by the component pushing mechanism 3005 are conveyed by the conveyor belt 3008 along the pair of guide rails 3007. With this arrangement, the components E stored in the stick 3009 are supplied to a component supply position.

If the lowest stick 3009 runs out of components in association with the component supply operations, the first and second chucks 3003 and 3004 hold a stick 3009 other than the lowest. In this state, the stick table 3002 is displaced to a support release position that releases the support of the stick 3009, thereby causing the lowest stick 3009 to fall by its own weight to the bottom inside the frame body 3001. Note that after disposing of the stick 3009 that has run out of components, the stick table 3002 returns to the support position for supporting a stick 3009 while the first and second chucks 3003 and 3004 are opened, thereby causing the remaining sticks 3009 to be placed on top of the stick table 3002, and supplying the components E from the next (lowest) stick 3009.

During the production of the mounted substrate, if a stick 3009 that has run out of components falls to the bottom inside the frame body 3001, a worker is able to replenish the stick feeder 3000 with a new stick.

Note that in each of the plurality of stick feeders 3000, the number of sticks 3009 storing the same type of component E may be different for every stick feeder 3000 in some cases. In such cases, the number of new sticks used to replenish the stick feeder 3000 and fill up the same components will be different for every stick feeder 3000. Also, the number of replenishing sticks may also change depending on the overall number of remaining components of a component type when replenishing the stick feeder 3000 with new sticks.

Here, the replenishment of the stick feeder 3000 with a new stick is managed by the first component replenishment management system 3 or the second component replenishment management system 3A. Hereinafter, the replenishment management by the first component replenishment management system 3 will be described.

In the first component replenishment management system 3, the replenishment target specifying unit 347 specifies all of the stick feeder 3000 that can be replenished with a new stick within a management period based on a specified time set by the setting unit 345 as component replenishment target devices. With this arrangement, “batch replenishment” becomes possible in which the stick replenishment work is performed all at once by a worker for the stick feeder 3000 that can be replenished with the new stick within the management period. For this reason, the worker is able to perform the “batch replenishment” of new sticks by treating the specified time that serves as the basis of the management period as an estimate of the work start time for the replenishment work. Consequently, the burden imposed on the worker by the replenishment work can be reduced.

Further, the replenishment timing specifying unit 348 specifies the replenishment timing of the same new stick in the management period for the stick feeder 3000 specified as component replenishment target devices by the replenishment target specifying unit 347. With this arrangement, the worker is able to perform the work of replenishing the stick feeder 3000 specified as the component replenishment target devices with the new stick at the same replenishment timing.

### Fourth Modified Embodiment

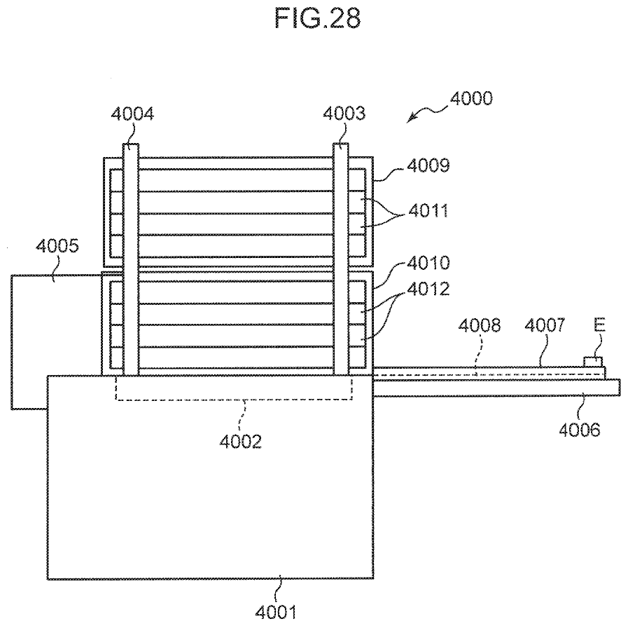

FIG. 28 is a diagram illustrating a stick feeder 4000 as the component supply device of a fourth modification. The stick feeder 4000 is installed in a component supply unit 24 of a mounter 2. A plurality of stick feeders 4000 can be disposed in parallel in the component supply unit 24.

The basic structure of the stick feeder 4000 is similar to that of the stick feeder 3000 described above. The stick feeder 4000 is provided with a first magazine 4009 that houses a stacked plurality of sticks 4011 storing the components E, and a second magazine 4010 that houses a stacked plurality of sticks 4012 storing the components E. The components E stored in the sticks 4011 and the components E stored in the sticks 4012 are of the same type. The first magazine 4009 and the second magazine 4010 function as component storage members that house the pluralities of sticks 4011 and 4012 storing the components E. In the example illustrated in FIG. 28, the sticks 4012 housed in the second magazine 4010 are stacked on top of a stick table 4002 disposed in an upper inner side of a frame body 4001, and the sticks 4011 housed in the first magazine 4009 are stacked on top of the sticks 4012.

In the stick feeder 4000, a component pushing mechanism 4005 pushes out the components E from the front of the lowest stick 4012 among the plurality of sticks 4012 housed in the second magazine 4010 disposed lower on top of the stick table 4002. The components E pushed out to the front by the component pushing mechanism 4005 are conveyed by a conveyor belt 4008 along a pair of guide rails 4007 supported on a guide frame 4006. With this arrangement, the components E stored in the stick 4012 are supplied to a component supply position.

If the lowest stick 4012 runs out of components in association with the component supply operations, the first and second chucks 4003 and 4004 hold a stick 4012 other than the lowest in the second magazine 4010, and all of the sticks 4011 in the first magazine 4009. In this state, the stick table 4002 is displaced to a support release position that releases the support of the sticks 4011 and 4012, thereby causing the lowest stick 4012 in the second magazine 4010 to fall by its own weight to the bottom inside the frame body 4001. Note that after disposing of the stick 4012 that has run out of components, the stick table 4002 returns to the support position for supporting sticks 4011 and 4012 while the first and second chucks 4003 and 4004 are opened, thereby causing the remaining sticks 4011 and 4012 to be placed on top of the stick table 4002, and supplying the components E in the second magazine 4010 from the next (lowest) stick 4012.

During the production of the mounted substrate, if all of the sticks 4012 inside the second magazine 4010 run out of components, the components E are supplied from the sticks 4011 inside the first magazine 4009. If all of the sticks 4012 inside the second magazine 4010 run out of components, a worker is able to replenish the stick feeder 4000 with a new magazine. Here, the replenishment of the stick feeder 4000 with a new magazine is managed by the first component replenishment management system 3 or the second component replenishment management system 3A. Hereinafter, the replenishment management by the first component replenishment management system 3 will be described.

In the first component replenishment management system 3, the replenishment target specifying unit 347 specifies all of the stick feeders 4000 that can be replenished with a new magazine within a management period based on a specified time set by the setting unit 345 as component replenishment target devices. With this arrangement, “batch replenishment” becomes possible in which the magazine replenishment work is performed all at once by a worker for the stick feeders 4000 that can be replenished with a new magazine within the management period. For this reason, the worker is able to perform the “batch replenishment” of new magazines by treating the specified time that serves as the basis of the management period as an estimate of the work start time for the replenishment work. Consequently, the burden imposed on the worker by the replenishment work can be reduced.

Further, the replenishment timing specifying unit 348 specifies the replenishment timing of the same new magazine in the management period for the stick feeder 4000 specified as component replenishment target devices by the replenishment target specifying unit 347. With this arrangement, the worker is able to perform the work of replenishing the stick feeder 4000 specified as the component replenishment target devices with the new magazine at the same replenishment timing.

### Fifth Modified Embodiment

Two or more types of component supply devices having different component supply methods may also be disposed respectively in each component supply unit 24 of the mounters 2. For example, assume that of the four component supply units 24 in one of the mounters 2, the AFs 241 are disposed in parallel in a first component supply unit 24, a plurality of splicing feeders are disposed in parallel in a second component supply unit 24, a plurality of the tray feeders 1000 or 2000 are disposed in parallel in a third component supply unit 24, and a plurality of the stick feeders 3000 or 4000 are disposed in parallel in a fourth component supply unit 24.

AF241, the tray feeders 1000 and 2000, and the replenishment of the stick feeders 3000 and 4000 with a new component storage member is managed by the first component replenishment management system 3 or the second component replenishment management system 3A.

Hereinafter, the replenishment management by the first component replenishment management system 3 will be described.

In the first component replenishment management system 3, the replenishment target specifying unit 347 specifies all of the component supply devices that can be replenished with a new component storage member within a management period based on a specified time set by the setting unit 345 as component replenishment target devices. With this arrangement, “batch replenishment” becomes possible in which the component storage member replenishment work is performed all at once by a worker for AF241, the tray feeders 1000 and 2000, and the stick feeders 3000 and 4000 that can be replenished with the new component storage member within the management period. For this reason, the worker is able to perform the “batch replenishment” of new component storage members by treating the specified time that serves as the basis of the management period as an estimate of the work start time for the replenishment work. Consequently, the burden imposed on the worker by the replenishment work can be reduced.

Further, the replenishment timing specifying unit 348 specifies the replenishment timing of the same new component storage member in the management period for the component supply device specified as component replenishment target devices by the replenishment target specifying unit 347. With this arrangement, the worker is able to perform the work of replenishing AF241, the tray feeders 1000 and 2000, and the stick feeders 3000 and 4000 specified as the component replenishment target devices with the new component storage member at the same replenishment timing.

Note that in the case where the specified length of time for prescribing the specified time is set to a length of time such that the time when splicing work to be performed on the splicing feeders is estimated to occur is close to the specified time, a worker is able to perform the splicing work on the splicing feeders together with the replenishment work for AF241, the tray feeders 1000 or 2000 and the stick feeders 3000 or 4000 within the management period based on the specified time.

The specific embodiments described above mainly include embodiments having the following configurations.

A component replenishment management system according to an aspect of the present disclosure is a system that manages a replenishment of component storage members storing components with respect to each of a plurality of component supply devices attached to a mounter that mounts the components on a substrate to produce a mounted substrate, a plurality of the component storage members being loadable into each of the plurality of component supply devices. This component replenishment management system includes an acquisition unit that acquires a management start time expressing a start time of the management of the replenishment of the component storage members with respect to each of the plurality of component supply devices, a setting unit that sets a specified period until a specified time after a predetermined specified length of time has elapsed from the management start time, a component supply monitoring unit that monitors a supply status of the components in each of the plurality of component supply devices, and specifies, for each of the plurality of component supply devices, a replenishment possibility time at which a preceding component storage member used to supply the components from among the plurality of component storage members runs out of components and replenishment with a new component storage member becomes possible, and a replenishment target specifying unit that specifies a component supply device whose replenishment possibility time is an earlier time than the specified time as a component replenishment target device targeted for replenishment with a new component storage member within the specified period.

According to the component replenishment management system, the replenishment target specifying unit specifies a component supply device targeted for replenishment of a new component storage member within a specified period set by a setting unit in a plurality of component supply devices. Here, the specified period set by the setting unit is a period until a specified time after a predetermined specified length of time has elapsed from a management start time acquired by an acquisition unit, and is a period based on the specified time. Additionally, the replenishment target specifying unit specifies a component supply device whose replenishment possibility time at which replenishment with a new component storage member is possible is an earlier time than the specified time as the component replenishment target device targeted for replenishment with a new component storage member within the specified period.

Thus, the component replenishment management system treats a component supply device that can be replenished with a new component storage member in the specified period based on the specified time as a component replenishment target device. With this arrangement, “batch replenishment” becomes possible in which the replenishment work of the component storage member is performed all at once by a worker for the component supply device that can be replenished with the component storage member in the specified period. For this reason, the worker is able to perform the “batch replenishment” of component storage members by treating the specified time that serves as the basis of the specified period as an estimate of the work start time for the replenishment work. Consequently, the frequency at which the worker goes to the mounters where the component supply devices are installed can be reduced, and the burden of replenishment work imposed on the worker can be reduced.

The component replenishment management system described above may further includes a replenishment timing specifying unit that specifies a same replenishment timing of a new component storage member within the specified period for all of the component replenishment target devices specified by the replenishment target specifying unit.

In this aspect, the replenishing timing of a component storage member with respect to all of the component replenishment target devices specified by the replenishment target specifying unit is the same timing within the specified period. With this arrangement, a worker is able to perform the work of replenishing the component replenishment target devices with component storage members at the same replenishment timing.

In the component replenishment management system described above, the replenishment timing specifying unit may be configured to specify a replenishment possibility time of interest that is a latest time from among the replenishment possibility times corresponding to the component replenishment target devices, and to specify any time between the replenishment possibility time of interest and the specified time as the replenishment timing.

The time window between the replenishment possibility time of interest and the specified time is a time window in which replenishment with a component storage member is possible for all component supply devices whose replenishment possibility time is an earlier time than the specified time. In other words, the time window between the replenishment possibility time of interest and the specified time is a time window in which “batch replenishment” is possible, such that the work of replenishing the component replenishment target devices with component storage members is performed all at once by a worker. The replenishment timing specifying unit specifies any such time between the replenishment possibility time of interest and the specified time as the replenishment time of a component storage member with respect to the component replenishment target devices. With this arrangement, a worker is able to perform the work of replenishing the component replenishment target devices with component storage members at any replenishment timing between the replenishment possibility time of interest and the specified time.

In the component replenishment management system described above, the setting unit may be configured to set a predetermined management period whose latest time is the specified time within the specified period, and the replenishment timing specifying unit may be configured to recognize, from among the component replenishment target devices, target devices of interest whose replenishment possibility time is a later time than an earliest time of the management period, specify the latest time among the replenishment possibility times corresponding to the target devices of interest as the replenishment possibility time of interest, and specify the replenishment possibility time of interest within the management period as the replenishment timing.

As described earlier, the time window between the replenishment possibility time of interest and the specified time is a time window in which “batch replenishment” is possible, such that the work of replenishing a component storage member with the component replenishment target devices by a worker is performed all at once. The replenishment possibility time of interest is the earliest time within the time window at which “batch replenishment” is possible. By treating the replenishment possibility time of interest as the replenishment timing of the component storage member with the component replenishment target devices, the worker is able to perform “batch replenishment” in a state with time to spare.

In the above component replenishment management system, the replenishment timing specifying unit may be configured to specify the specified time as the replenishment timing.

In this aspect, a worker is able to perform the work of replenishing the component replenishment target devices with component storage members by treating the specified time as the replenishment timing.

The component replenishment management system described above may further include a recommended start time specifying unit that specifies a recommended next start time recommended as a start time of replenishment management next time in a time window after the specified time. The recommended start time specifying unit specifies the earliest time among the replenishment possibility times corresponding to remaining component supply devices other than the component replenishment target devices among the plurality of component supply devices as the recommended next start time.

In this aspect, a worker is able to grasp the recommended next start time as the start time for replenishment management next time after the specified time. After grasping the recommended next start time, the worker is able to predict the timing of the next replenishment work by adding a predetermined specified length of time to the recommended next start time. This arrangement makes it easy for the worker to create a plan for replenishment work.

In the component replenishment management system described above, the setting unit may be configured to divide a target period of replenishment management of the component storage members after the management start time into a plurality of the specified periods by treating the specified length of time as a time interval, and the replenishment target specifying unit may be configured to specify the component replenishment target devices for each of the plurality of specified periods.

In this aspect, the replenishment target specifying unit specifies the component replenishment target devices targeted for replenishment of a new component storage member for each of a plurality of specified periods divided by treating the specified length of time as a time interval. With this arrangement, “batch replenishment” becomes possible in which the component storage member replenishment work is performed all at once by a worker for the component supply devices that can be replenished with a component storage member in each of the plurality of specified periods.

In the above component replenishment management system, the setting unit may be configured to set the time interval in each of the plurality of specified periods to a fixed interval.

In this aspect, a worker is able to perform the work of replenishing the component replenishment target devices with component storage members periodically on a fixed time interval.

The component replenishment management system described above may further include an operation unit that receives an operation of inputting command information related to the setting of the time interval of the specified periods. Additionally, the setting unit sets the time interval in each of the plurality of specified periods based on the command information.

In this aspect, the time interval in each of the plurality of specified periods can be designated by a worker through the operation unit. This arrangement makes it easy for the worker to create a plan for the work of replenishing the component replenishment target devices with component storage members.

The component replenishment management system described above may further include an adjustment unit that calculates a number of the component replenishment target devices specified by the replenishment target specifying unit for each of the plurality of specified periods, and adjusts the number of the component replenishment target devices in each of the plurality of specified periods based on a result of the calculation. With regard to the number of component replenishment target devices in respective specified periods adjacent to each other in a time series, in a case where a number in a first specified period of interest that is earlier in a time-series order is greater than a predetermined reference number, while in addition, a number in a second specified period of interest that is later in the time-series order is less than the reference number, the adjustment unit performs a replenishment count adjustment process of allocating a portion of the component replenishment target devices in the first specified period of interest as the component replenishment target devices targeted for replenishment with a new component storage member in the second specified period of interest.

In this aspect, the adjustment unit performs a replenishment count adjustment process that adjusts the number of component replenishment target devices in each of the plurality of specified periods. With regard to the number of component replenishment target devices in respective specified periods adjacent to each other in a time series, in a case where a number in a first specified period of interest that is earlier in a time-series order is greater than a predetermined reference number, while in addition, a number in a second specified period of interest that is later in the time-series order is less than the reference number, the setting unit performs the replenishment count adjustment process. In the replenishment count adjustment process, the setting unit allocates a portion of the component replenishment target devices in the first specified period of interest as component replenishment target devices in the second specified period of interest. With this arrangement, the burden of the work of replenishing the component replenishment target devices with component storage members can be leveled out among the plurality of specified periods.

In the component replenishment management system described above, the component supply monitoring unit may be configured to specify, for each of the plurality of component supply devices, a remaining count warning time at which a total number of remaining components stored in the plurality of component storage members will reach a predetermined component remaining count warning value, and the adjustment unit may be configured not to perform the replenishment count adjustment process in a case where the remaining count warning time is included within a third specified period of interest that is adjacent later in the time series than the second specified period of interest in the plurality of specified periods.

In the replenishment work with respect to the component replenishment target device in the second specified period of interest, the replenishment work with respect to the component replenishment target device whose remaining count warning time is included within the third specified period of interest that is adjacent later in the time series than the second specified period of interest becomes urgent work, and careful work is demanded. In this way, in the case where the remaining count warning time is included within the third specified period of interest, and the replenishment work in the second specified period of interest is expected to be urgent work, the adjustment unit does not perform the replenishment count adjustment process. With this arrangement, a portion of the component replenishment target devices in the first specified period of interest is not allocated to the second specified period of interest. For this reason, a worker is able to concentrate on the urgent replenishment work in the second specified period of interest.

A component mounting system according to another aspect of the present disclosure includes a mounter to which a plurality of component supply devices loadable with a plurality of component storage members storing components is attached, the mounter mounting the components on a substrate to produce a mounted substrate, and the component replenishment management system that manages a replenishment of the component storage members with respect to each of the plurality of component supply devices.

According to the component mounting system, a component replenishment management system capable of reducing the burden of replenishment work imposed on the worker is provided, and therefore an interruption in the supply of components from the component supply devices caused by a delay in the replenishment work by the worker during the production of a mounted substrate can be suppressed as much as possible. With this arrangement, a drop in the production efficiency of the mounted substrate can be suppressed.

As described above, according to the present disclosure, there is provided a component replenishment management system capable of reducing the burden imposed on the worker by the replenishment work of replenishing a component supply device with a component storage member, as well as a component mounting system provided with the same.

What is claimed is:

1. A component replenishment management system that manages a replenishment of component storage members storing components with respect to each of a plurality of component supply devices attached to a mounter that mounts the components on a substrate to produce a mounted substrate, a plurality of the component storage members being loadable into each of the plurality of component supply devices, the component replenishment management system comprising:
an acquisition unit configured to acquire a management start time expressing a start time of the management of the replenishment of the component storage members with respect to each of the plurality of component supply devices;
a setting unit configured to set a specified period until a specified time after a predetermined specified length of time has elapsed from the management start time;
a component supply monitoring unit configured to monitor a supply status of the components in each of the plurality of component supply devices, and specify, for each of the plurality of component supply devices, a replenishment possibility time at which a preceding component storage member used to supply the components from among the plurality of component storage members runs out of components and replenishment with a new component storage member becomes possible; and
a replenishment target specifying unit configured to specify a component supply device whose replenishment possibility time is an earlier time than the specified time as a component replenishment target device targeted for replenishment with a new component storage member within the specified period.

2. The component replenishment management system according to claim 1, further comprising: a replenishment timing specifying unit configured to specify a same replenishment timing of a new component storage member within the specified period for all of the component replenishment target devices specified by the replenishment target specifying unit.

3. The component replenishment management system according to claim 2, wherein the replenishment timing specifying unit is configured to specify a replenishment possibility time of interest that is a latest time from among the replenishment possibility times corresponding to the component replenishment target devices, and specify any time between the replenishment possibility time of interest and the specified time as the replenishment timing.

4. The component replenishment management system according to claim 3, wherein the setting unit is configured to set a predetermined management period whose latest time is the specified time within the specified period, and the replenishment timing specifying unit is configured to recognize, from among the component replenishment target devices, target devices of interest whose replenishment possibility time is a later time than an earliest time of the management period, specify the latest time among the replenishment possibility times corresponding to the target devices of interest as the replenishment possibility time of interest, and specify the replenishment possibility time of interest within the management period as the replenishment timing.

5. The component replenishment management system according to claim 3, wherein the replenishment timing specifying unit is configured to specify the specified time as the replenishment timing.

6. The component replenishment management system according to claim 1, further comprising:
a recommended start time specifying unit configured to specify a recommended next start time recommended as a start time of replenishment management next time in a time window after the specified time, wherein
the recommended start time specifying unit is configured to specify the earliest time among the replenishment possibility times corresponding to remaining component supply devices other than the component replenishment target devices among the plurality of component supply devices as the recommended next start time.

7. The component replenishment management system according to claim 1, wherein
the setting unit is configured to divide a target period of replenishment management of the component storage members after the management start time into a plurality of the specified periods by treating the specified length of time as a time interval, and
the replenishment target specifying unit is configured to specify the component replenishment target devices for each of the plurality of specified periods.

8. The component replenishment management system according to claim 7, wherein the setting unit is configured to set the time interval in each of the plurality of specified periods to a fixed interval.

9. The component replenishment management system according to claim 7, further comprising: an operation unit configured to receive an operation of inputting command information related to the setting of the time interval of the specified periods, wherein
the setting unit is configured to set the time interval in each of the plurality of specified periods based on the command information.

10. The component replenishment management system according to claim 7, further comprising: an adjustment unit configured to calculate a number of the component replenishment target devices specified by the replenishment target specifying unit for each of the plurality of specified periods, and adjust the number of the component replenishment target devices in each of the plurality of specified periods based on a result of the calculation, wherein
with regard to the number of component replenishment target devices in respective specified periods adjacent to each other in a time series, in a case where a number in a first specified period of interest that is earlier in a time-series order is greater than a predetermined reference number, while in addition, a number in a second specified period of interest that is later in the time-series order is less than the reference number, the adjustment unit is configured to perform a replenishment count adjustment process of allocating a portion of the component replenishment target devices in the first specified period of interest as component replenishment target devices targeted for replenishment with a new component storage member in the second specified period of interest.

11. The component replenishment management system according to claim 10, wherein
the component supply monitoring unit is configured to specify, for each of the plurality of component supply devices, a remaining count warning time at which a total number of remaining components stored in the plurality of component storage members will reach a predetermined component remaining count warning value, and
the adjustment unit does not perform the replenishment count adjustment process in a case where the remaining count warning time is included within a third specified period of interest that is adjacent later in the time series than the second specified period of interest in the plurality of specified periods.

12. A component mounting system comprising:
a mounter to which a plurality of component supply devices loadable with a plurality of component storage members storing components is attached, the mounter being configured to mount the components on a substrate to produce a mounted substrate; and
the component replenishment management system according to claim 1 that manages a replenishment of the component storage members with respect to each of the plurality of component supply devices.

13. The component replenishment management system according to claim 2, further comprising:
a recommended start time specifying unit configured to specify a recommended next start time recommended as a start time of replenishment management next time in a time window after the specified time, wherein
the recommended start time specifying unit is configured to specify the earliest time among the replenishment possibility times corresponding to remaining component supply devices other than the component replenishment target devices among the plurality of component supply devices as the recommended next start time.

14. The component replenishment management system according to claim 3, further comprising:
a recommended start time specifying unit configured to specify a recommended next start time recommended as a start time of replenishment management next time in a time window after the specified time, wherein
the recommended start time specifying unit is configured to specify the earliest time among the replenishment possibility times corresponding to remaining component supply devices other than the component replenishment target devices among the plurality of component supply devices as the recommended next start time.

15. The component replenishment management system according to claim 4, further comprising:
a recommended start time specifying unit configured to specify a recommended next start time recommended as a start time of replenishment management next time in a time window after the specified time, wherein
the recommended start time specifying unit is configured to specify the earliest time among the replenishment possibility times corresponding to remaining component supply devices other than the component replenishment target devices among the plurality of component supply devices as the recommended next start time.

16. The component replenishment management system according to claim 2, wherein
the setting unit is configured to divide a target period of replenishment management of the component storage members after the management start time into a plurality of the specified periods by treating the specified length of time as a time interval, and
the replenishment target specifying unit is configured to specify the component replenishment target devices for each of the plurality of specified periods.

17. The component replenishment management system according to claim 3, wherein
the setting unit is configured to divide a target period of replenishment management of the component storage members after the management start time into a plurality of the specified periods by treating the specified length of time as a time interval, and
the replenishment target specifying unit is configured to specify the component replenishment target devices for each of the plurality of specified periods.

18. The component replenishment management system according to claim 4, wherein
the setting unit is configured to divide a target period of replenishment management of the component storage members after the management start time into a plurality of the specified periods by treating the specified length of time as a time interval, and
the replenishment target specifying unit configured to specify the component replenishment target devices for each of the plurality of specified periods.
